(19) United States
(12) Patent Application Publication
(10) Pub. No.: US 2024/0334784 A1
(43) Pub. Date: Oct. 3, 2024

(54) Display Apparatus

(71) Applicant: LG Display Co., Ltd., Seoul (KR)

(72) Inventors: MinSeob Song, Jeonju-si (KR); Kyuwon Kyoung, Seoul (KR)

(21) Appl. No.: 18/432,830

(22) Filed: Feb. 5, 2024

(30) Foreign Application Priority Data
Mar. 31, 2023 (KR) 10-2023-0042766

(51) Int. Cl. H10K 59/80; H10K 59/122; H10K 59/40

(52) U.S. Cl. CPC H10K 59/873; H10K 59/122; H10K 59/40

(57) ABSTRACT

A display device may comprise a substrate including an active area and a first non-active area adjacent to the active area and including a bending area, a dam portion disposed on the substrate, an encapsulation layer on the dam portion, a touch unit on the encapsulation layer, a cover layer on the touch unit, and a partition in contact with the cover layer.

### CROSS-REFERENCE TO RELATED APPLICATION

This application claims the benefit of and priority to Republic of Korea Patent Application No. 10-2023-0042766 filed on Mar. 31, 2023 in the Republic of Korea, which is hereby incorporated by reference in its entirety.

### BACKGROUND

### Technical Field

The present disclosure relates to a display device, and more specifically, to a display device in which defects of cracks and moisture permeation are prevented or at least reduced by disposing a cover layer and a partition.

### Discussion of the Related Art

Recent display devices capable of displaying various types of information and interacting with users viewing the information are required to have various sizes, shapes, and functions.

These display devices include a liquid crystal display apparatus (LCD), an electrophoretic display apparatus (FPD), a light emitting diode display apparatus (LED), and the like.

As display devices are used in a variety of ways, the display devices are being designed in more diverse manners to reduce an area of a non-active area where images are not displayed for user's aesthetics. A high ratio of a size of an emission active area to a size of the non-active area is one of the most important design challenges. By folding an entirety or a part of the non-active area and placing it on a rear surface of the active area, the non-active area is hidden from users. Thus, it is possible to provide a display device in which the ratio of the active area that is visible to users and the non-active area is increased.

In order to provide a display device with an increased ratio of an active area visible to users, the substrate may be bent so that a portion of the substrate has a curved area (or bending area). Lines disposed in a bending area may crack due to mechanical stress applied to the bending area (or bent area). Due to the cracks, external moisture or oxygen may be penetrated to cause electric erosion or corrosion of the lines, which may interfere with an image operation and cause abnormal images to be displayed. Additionally, an insulating layer and protective layer within the display device may be etched, causing sharp steps and bends and leading to a defect in which stains are visible to users.

Accordingly, various studies are being conducted to prevent electric erosion or corrosion of lines disposed in the bending area of the display device, but these are still insufficient and development thereof is urgently needed.

### SUMMARY

An object to be achieved by the present disclosure is to provide a display device including a cover layer and a partition to eliminate or at least reduce cracks and disconnections in lines caused by mechanical stress in a bending area formed during or after a bending process of a substrate.

Another object to be achieved by the present disclosure is to provide a display device in which a touch insulating layer is formed of an organic material in order to remove cracks and disconnections in lines in a bending area and solve a defect in which spots are recognized due to sharp steps and bends in the display device.

According to an aspect of the present disclosure, a display device may comprise a substrate including an active area and a first non-active area adjacent to the active area, the first non-active area including a bending area, a dam portion on the substrate, an encapsulation layer on the dam portion, a touch unit configured to sense touch of the display device, the touch unit on the encapsulation layer, a cover layer on the touch unit, and a partition in contact with the cover layer.

In one embodiment, a display device comprises: a substrate including an active area and a non-active area around the active area, the non-active area including a bending area; a dam portion in the non-active area, the dam portion around the active area; an encapsulation layer on the dam portion; and a touch unit on the encapsulation layer, the touch unit comprising: a first touch electrode; a second touch electrode; and an insulating layer between the first touch electrode and the second touch electrode, the insulating layer comprising an organic material.

In one embodiment, a display device comprises: a substrate including an active area and a non-active area, the non-active area including a bending area; a light emitting element in the active area, the light emitting element configured to emit light; a dam in the non-active area of the substrate; an encapsulation layer on the light emitting element in the active area, the encapsulation layer extending from the active area to the non-active area and in contact with the dam in the non-active area; a partition between the dam and the bending area in the non-active area; and a cover layer on the encapsulation layer, the cover layer extending from the active area to the non-active area such that an end of the cover layer contacts the partition in the non-active area.

Since a display device according to an exemplary embodiment of the present disclosure includes a cover layer and a partition, defects of cracks and disconnections in lines caused by mechanical stress in a bending area during or after a bending process of a substrate can be prevented or eliminated.

Since a display device according to an exemplary embodiment of the present disclosure includes a touch insulating layer formed of an organic material, cracks and disconnections in lines in a bending area can be removed and a defect of spots being visible due to sharp steps and bends in the display device can be resolved.

Since a display device according to an exemplary embodiment of the present disclosure may avoid or reduce the occurrence of cracks or disconnections in lines, it can be operated normally, so that it is possible to provide users with a display device having improvements in aesthetics, lifespan, and reliability and allowing for low-power and/or reduced power consumption.

The effects according to the present disclosure are not limited to the contents exemplified above, other effects not mentioned will be clearly understood by those skilled in the art from the description below.

### BRIEF DESCRIPTION OF THE DRAWINGS

FIG. 1 is a view illustrating a display device according to an exemplary embodiment of the present disclosure.

FIG. 2 is a plan view of a display driver according to an exemplary embodiment of the present disclosure.

FIG. 3 is a plan view of a touch unit according to an exemplary embodiment of the present disclosure.

FIG. 4 is a view illustrating arrangements of emission portions and a non-emission portion of the display device according to an exemplary embodiment of the present disclosure.

FIG. 5 is a cross-sectional view taken along line I-I′ of FIG. 4 according to an exemplary embodiment of the present disclosure.

FIG. 6 is a cross-sectional view taken along line II-II′ of FIG. 3 according to an exemplary embodiment of the present disclosure.

FIG. 7 is a cross-sectional view of a display device according to another exemplary embodiment of the present disclosure.

FIG. 8 is a cross-sectional view of a display device according to another exemplary embodiment of the present disclosure.

FIG. 9 is a cross-sectional view of a display device according to another exemplary embodiment of the present disclosure.

FIG. 10 is a plan view of an area where a hole H is disposed according to an exemplary embodiment of the present disclosure.

FIG. 11 is a cross-sectional view taken along line III-III′ of FIG. 10 according to an exemplary embodiment of the present disclosure.

FIG. 12 is a cross-sectional view of an emission portion according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure. The present disclosure is defined only by the scope of the claims.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

In describing temporal relationship, terms such as “after,” “subsequent to,” “next to,” “before,” and the like may include cases where any two events are not consecutive, unless the term “immediately” or “directly” is explicitly used.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

In describing elements of the present disclosure, terms such as first, second, A, B, (a), (b), and the like may be used. Such terms are used for merely distinguishing the elements from other elements and the corresponding elements are not limited in their essence, sequence, or the number by the terms. It will be understood that when an element is “connected” or “coupled” to another element, it can be directly connected or coupled to the other element, but unless specifically stated otherwise, it should be understood that other components may be “interposed” between the respective elements that are indirectly connected or coupled.

The term “at least one” should be understood as including any and all combinations of one or more of the associated listed elements. For example, the meaning of “at least one of a first element, a second element, and a third element” denotes the combination of all elements proposed from two or more of the first element, the second element, and the third element as well as the first element, the second element, or the third element.

In the present disclosure, examples of the “device” may include display devices such as a liquid crystal module (LCM) and an organic light emitting display module (OLED module), including a display panel and a driver for driving the display panel. Also, examples of the display device may include a set device (or a set apparatus) or a set electronic device such as a notebook computer, a TV, a computer monitor, an equipment apparatus including an automotive apparatus or another type of apparatus for vehicles, or a mobile electronic device such as a smartphone or an electronic pad, which is a complete product (or a final product) including an LCM and an OLED module.

Therefore, in the present disclosure, examples of the display device may include a display device itself, such as an LCM, an OLED module and the like and a set device, which is a final consumer device or an application product including the LCM, the OLED module, and the like.

In some embodiments, an LCM and an OLED module including a display panel and a driver may be referred to as a display device, and an electronic device, which is a final product including an LCM and an OLED module may be referred to as a set device. For example, the display device may include a display panel, such an LCD or an OLED module, and a source printed circuit board (PCB), which is a controller for driving the display panel. The set device may further include a set PCB, which is a set controller electrically connected to the source PCB to control the set device overall.

As display panels used in embodiments of the present disclosure, any type of display panels, including a liquid crystal display panel, an organic light emitting diode (OLED) display panel, and an electroluminescent display panel may be used, and embodiments of the present disclosure are not limited thereto. Also, a shape or a size of a display panel applied to a display device according to embodiments of the present disclosure is not limited.

The features of various embodiments of the present disclosure can be partially or entirely bonded to or combined with each other and can be interlocked and operated in technically various ways, and the exemplary embodiments can be carried out independently of or in association with each other.

Hereinafter, embodiments of the present disclosure will be considered through attached drawings and examples. The scale of elements shown in the drawings is different from an actual scale for convenience of explanation, and is therefore not limited to the scale shown in the drawings.

Hereinafter, various embodiments of the present disclosure will be described in detail with reference to the drawings.

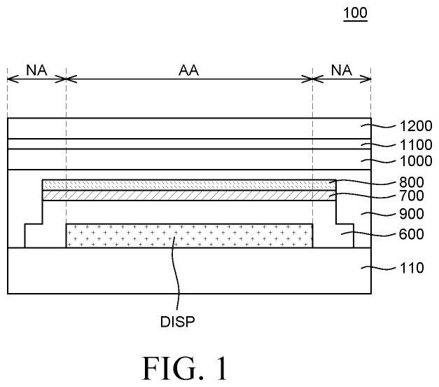

FIG. 1 is a view illustrating a display device according to an exemplary embodiment of the present disclosure.

Referring to FIG. 1, a display device 100 may include a substrate 110 having an active area AA and a non-active area NA.

A display driver DISP including a thin film transistor and an emission element layer may be disposed on the substrate 110. An encapsulation layer 600, a touch unit 700, and a cover layer 800 may be disposed on the display driver DISP.

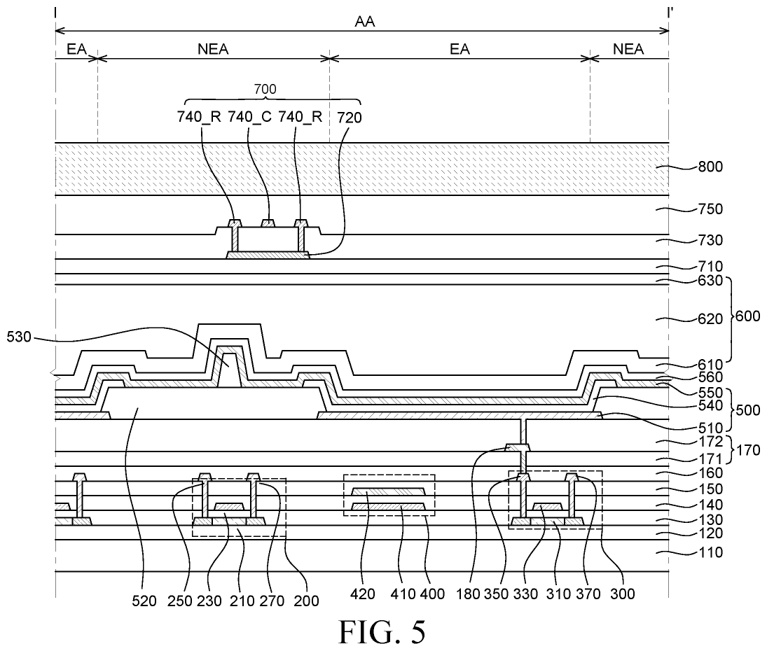

The display driver DISP, the encapsulation layer 600, the touch unit 700, and the cover layer 800 will be described in detail later with reference to FIG. 5.

A polarizing plate 1000 may be disposed on the cover layer 800. The polarizing plate 1000 can selectively transmit light and reduce reflection of external light incident on the display device. For example, the display device may include various metal materials applied to thin film transistors, an emission element layer, and lines. External light incident on the display device may be reflected from the metal material, and visibility of the display device 100 may be reduced due to reflection of the external light. Therefore, by disposing the polarizing plate 1000 on one surface of the display device 100, reflection of external light can be prevented and outdoor visibility of the display device 100 can be improved.

The polarizing plate 1000 may be omitted depending on a structure of the display device 100, or the like.

A first adhesive layer 900 may be disposed between the cover layer 800 and the polarizing plate 1000. The cover layer 800 and the polarizing plate 1000 can be adhered (e.g., attached) using the first adhesive layer 900.

The first adhesive layer 900 may be formed of an adhesive material, and for example, may be formed of optically clear adhesive (OCA), optically clear resin (OCR), or pressure sensitive adhesive (PSA), but is limited thereto.

The first adhesive layer 900, together with the encapsulation layer 600, can protect the display driver DISP from external moisture, oxygen, or foreign materials.

A front member 1200 may be disposed on the polarizing plate 1000. The front member 1200 can protect the polarizing plate 1000, the display driver DISP, and the touch unit 700 disposed below the front member 1200 from external impacts, moisture, heat, and the like. The front member 1200 may be formed of a material that has impact resistance and light transparency. For example, the front member 1200 may be a substrate formed of glass, or may be a film formed of a plastic material such as polymethylmethacrylate (PMMA), polyimide (PI), or polyethylene terephthalate (PET), but the present disclosure is not limited thereto. Additionally, the front member 1200 may be referred to various names such as a cover window, a window cover, or a cover glass, but is not limited thereto.

The front member 1200 may be bonded to the substrate 110 through a bonding process after a manufacturing process of components disposed on the substrate 110 is completed.

A second adhesive layer 1100 may be disposed between the polarizing plate 1000 and the front member 1200. The polarizing plate 1000 and the front member 1200 can be bonded using the second adhesive layer 1100.

The second adhesive layer 1100 may be formed of an adhesive material, and for example, may be formed of optically clear adhesive (OCA), optically clear resin (OCR), or pressure sensitive adhesive (PSA), but is limited thereto.

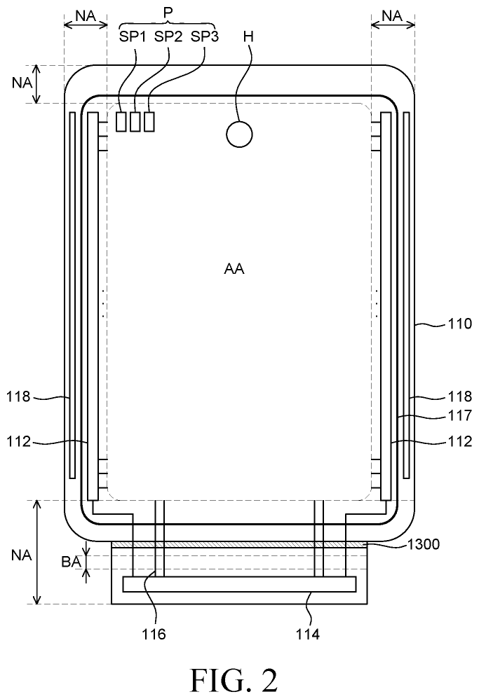

FIG. 2 is a plan view of a display driver according to an exemplary embodiment of the present disclosure.

Referring to FIG. 2, the substrate 110 may include an active area AA and a non-active area NA surrounding the active area AA. A first non-active area NA1 of the substrate 110 may be adjacent to the active area AA and may be disposed outside the active area AA.

The active area AA is an area where pixels P are disposed and an image is displayed.

The pixel P disposed in the active area AA may further include a plurality of sub-pixels SP1, SP2, and SP3. The plurality of sub-pixels SP1, SP2, and SP3 are individual units that emit light, and a plurality of sub-pixels SP may emit light of red, green, blue, and/or white, but embodiments of the present disclosure are not limited thereto.

The active area AA may include an organic light emitting diode. Each of the plurality of sub-pixels SP1, SP2, and SP3 may have an emission element layer for displaying an image and a thin film transistor for driving the emission element layer.

One sub-pixel SP may include a plurality of transistors T, a capacitor C, and a plurality of lines. For example, one sub-pixel SP may have a structure (2TIC) including two transistors and one capacitor, but is not limited thereto. One sub-pixel SP may have structures such as 3TIC, 4TIC, 5TIC, 6TIC, 7TIC, 3T2C, 4T2C, 5T2C, 6T2C, 7T2C, 8T2C, and the like, and can be implemented depending on a structure and type of the thin film transistor.

The non-active area NA is an area where an image is not displayed, and is an area where various lines and driving circuits for driving the plurality of sub-pixels SP disposed in the active area AA are disposed. Since the non-active area NA is not an area where an image is displayed, a portion of the non-active area NA of the substrate 110 may be bent to thereby reduce the non-active area NA, for example, a bezel area.

The non-active area NA may include the first non-active area NA1 disposed around the active area AA and a second non-active area NA2 disposed inside the active area AA.

As shown in FIG. 2, the first non-active area NA1 may be disposed around the active area AA. For example, the first non-active area NA1 may be an area surrounding the active area AA. The first non-active area NA1 may be an area extending from the active area AA. Alternatively, the first non-active area NA1 may be an area where the plurality of sub-pixels SP are not disposed, but is not limited thereto.

FIG. 2 illustrates that the first non-active area NA1 surrounds a rectangular active area AA. However, a shape of the active area AA and a shape and an arrangement of the first non-active area NA1 adjacent to the active area AA are not limited to an example shown in FIG. 2. The active area AA and the non-active area NA may have a shape suitable for a design of an electronic device equipped with the display device 100. In the case of a display device of an apparatus wearable by a user, it may have a circular shape such as a wristwatch, and concepts of the exemplary embodiments of the present disclosure may also be applied to free-form display devices applicable to vehicle dashboards, and the like. Exemplary shapes of the active area AA may be pentagonal, hexagonal, circular, or oval, but are not limited thereto.

The first non-active area NA1 is an area where various lines and driving circuits for driving the plurality of sub-pixels SP1, SP2, and SP3 disposed in the active area AA are disposed. For example, various ICs and driving circuits, such as a gate driver and a data driver, may be disposed in the first non-active area NA1. The first non-active area NA1 may be a bezel area and is not limited to the term.

The display device 100 of the present disclosure may include various additional elements for generating various signals or driving the plurality of sub-pixels SP1, SP2, and SP3 in the active area AA. For example, the driving circuit for controlling (or driving) the plurality of sub-pixels SP1, SP2, and SP3 includes gate drivers 112, data signal lines, a multiplexer MUX, an electrostatic discharge (ESD) circuit, power lines, an inverter circuit, connection lines 116, and the like. The power line may be a high-potential voltage line and/or a low-potential voltage line, but embodiments of the present disclosure are not limited thereto. The display device 100 may also include additional elements other than functions for driving the plurality of sub-pixels SP1, SP2, and SP3. For example, the display device 100 may include additional elements that provide a touch detection function, a user authentication function (e.g., fingerprint recognition), a multi-level pressure detection function, and a tactile feedback function, and the exemplary embodiments of the present disclosure are not limited thereto. The mentioned additional elements may be located in the first non-active area NA1 or an external circuit connected to a connection interface, but embodiments of the present disclosure are not limited thereto.

A pad unit 114 (e.g., a pad area) may be disposed on one side of the first non-active area NA1. The pad unit 114 may be a metal pattern to which external modules, such as a flexible printed circuit board (FPCB) and a chip-on-film (COF), are bonded. The pad unit 114 is shown as being disposed on one side of the substrate 110, but a shape and arrangement of the pad unit 114 are not limited thereto.

The gate drivers 112 that provide a gate signal to the thin film transistors may be disposed on one side and the other side of the first non-active area NA1. The gate driver 112 includes various gate driver circuits, and the gate driver circuits may be formed directly on the substrate 110. In this case, the gate driver 112 may be a gate-in-panel (GIP), and is not limited to the term.

The gate driver 112 may be disposed between the active area AA and a dam portion 117 (e.g., a dam). Between the active area AA and the pad unit 114 of the first non-active area NA1, a high-potential voltage line VDD, a low-potential voltage line VSS, a multiplex MUX, an electrostatic discharge (ESD) circuit, and the connection lines 116 may be disposed, but embodiments of the present disclosure are not limited thereto.

The high-potential voltage line VDD, the low-potential voltage line VSS, the multiplex MUX, and the connection lines 116 may be disposed between the active area AA and a bending area BA. The high-potential voltage line VDD, the low-potential voltage line VSS, the multiplexer MUX, and the connection lines 116 may be disposed in a non-bending area adjacent to the active area AA.

The connection lines 116 may be disposed in a portion of the first non-active area NA1. The connection lines 116 may be disposed in the bending area BA and the non-bending area adjacent to the bending area BA of the display device.

The connection line 116 may be a component for transmitting a signal (e.g., a voltage) from an external module bonded to the pad unit 114 to the active area AA or a circuit unit such as the gate driver 112. For example, various signals and voltages, such as various gate signals, data signals, high-potential voltages, and low-potential voltages, may be transmitted through the connection lines 116.

The connection lines 116 can be divided into a power connection line and/or a signal connection line depending on a voltage and/or video signal being transmitted.

The power connection line can transmit a voltage supplied from the external module to the active area AA. The power connection line may be connected to the low-potential voltage line VSS, the high-potential voltage line VDD, and a gate low-voltage line and/or gate high-voltage line included in the gate driver, but is not limited thereto.

The signal connection line can transmit signals supplied from an external module to the active area AA. The signal connection line may be connected to a scan line and/or a data line, but is not limited thereto.

The dam portion 117 may be disposed in the first non-active area NA1 to surround an entirety or part of the active area AA. The dam portion 117 may be adjacent to the active area AA and may be disposed outside the active area AA.

The dam portion 117 may be disposed along a periphery of the active area AA to control a flow of a layer containing an organic material in the encapsulation layer disposed on the emission element layer. One dam portion 117 or a plurality of dam dams 117 may be configured, and exemplary embodiments of the present disclosure are not limited thereto.

A panel crack detector 118 may be further disposed in a portion of the non-active area NA of the substrate 110.

The panel crack detector 118 may be disposed between an end point (or end) of the substrate 110 and the dam portion 117. Alternatively, the panel crack detector 118 may be disposed below the dam portion 117 and at least partially overlap the dam portion 117. The panel crack detector 118 is disposed on an outside of the display device and can detect defects such as cracks that may occur on the outside of the display device.

A hole H may be further included inside the active area AA. The hole H is disposed between the plurality of sub-pixels SP in the active area AA. The hole H may be an area where an optical component such as a camera or optical sensor is disposed. Examples of the optical sensor may include a proximity sensor, an infrared sensor, an ultraviolet sensor, and the like, but embodiments of the present disclosure are not limited thereto. Since the hole H includes a hole H that penetrates some components of the display device 100 to place the optical component, a space for placing the optical component can be secured.

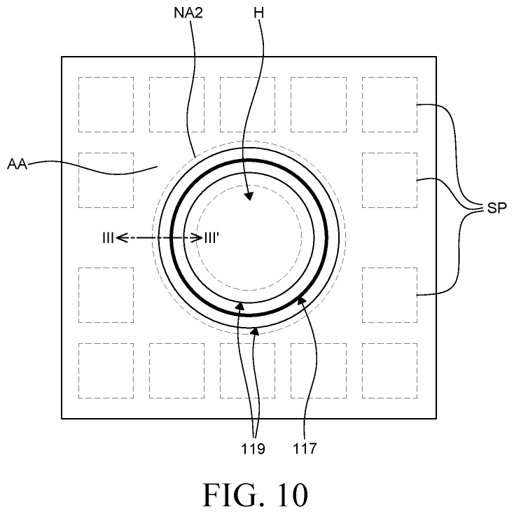

The second non-active area NA2 (shown in FIG. 10) may be disposed around the hole H. For example, the second non-active area NA2 may be an area surrounding the hole H, and the second non-active area NA2 may be an area disposed between the active area AA and the hole H. The second non-active area NA2 may be an area where the plurality of sub-pixels SP are not disposed, but is not limited thereto.

A partition 1300 that controls the cover layer 800 may be disposed on one side of the first non-active area NA1. The partition 1300 may be disposed between the active area AA and the bending area BA. The partition 1300 may be disposed in the dam portion 117 and the bending area BA.

The partition 1300 may be disposed along a periphery of the bending area BA to control a flow of the cover layer 800 formed of an organic material. One partition 1300 or a plurality of partitions 1300 may be configured, and embodiments of the present disclosure are not limited thereto.

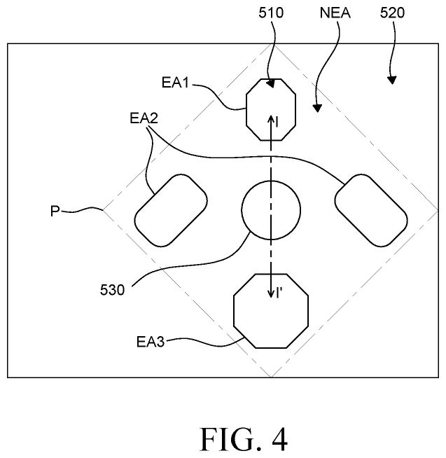

FIG. 4 is a view illustrating arrangements of emission portions and a non-emission portion of the display device according to an exemplary embodiment of the present disclosure.

The active area AA of the substrate 110 may include emission portions EA and a non-emission portion NEA disposed between the emission portions EA.

The emission portions EA are areas emitting light from the emission element layer in the sub-pixel SP, and each sub-pixel may include the emission portions. A plurality of the emission portions EA may be disposed on the substrate and spaced apart from each other. The non-emission portion NEA may be disposed to surround the emission portions.

The emission portions EA are areas in an emission layer where light is emitted to the outside. Referring to FIG. 5, the emission portions EA may be areas where a bank 520 is not disposed.

The non-emission portion NEA is an area in the emission layer where light is not emitted to the outside. Referring to FIG. 5, it may be an area where the bank 520 is disposed.

A plurality of emission portions emitting different colors may be located in the emission portions EA. For example, the plurality of emission portions may include a first emission portion EA1 that emits red light, a second emission portion EA2 that emits green light, and a third emission portion EA3 that emits blue light. Alternatively, the plurality of emission portions may include a white emission portion, and the like, but the present disclosure is not limited thereto.

Each of the emission portions EA is formed in a specific shape and disposed in a specific manner as shown in FIG. 4, but the emission portions EA of the display device 100 according to the present disclosure are not disposed only in this specific manner and can be disposed in various shapes and manners. For example, an exemplary shape of each emission portion EA may be quadrangular, pentagonal, hexagonal, octagonal, circular, or oval, but is not limited thereto. For example, the first emission portion EA1 and the third emission portion EA3 may have the same shape. In one embodiment, the first emission portion EA1 and the third emission portion EA3 may have the same shape but have different sizes as shown in FIG. 4. The second emission portion EA2 may have a different shape from the first emission portion EA1. The second emission portion EA2 may have a different shape from the third emission portion EA3. For example, the second emission portion EA2 may have a different shape from the first emission portion EA1 and the third emission portion EA3.

One pixel P may be composed of a plurality of sub-pixels or emission portions that emit light of the same color as shown in FIG. 4. For example, at least two second sub-pixels SP2 or at least two second emission portions EA2 may be disposed in one pixel P. At least two second emission portions EA2 that emit green light may be disposed in one pixel P, but embodiments of the present disclosure are not limited thereto.

The third emission portion EA3 may have a larger area than other emission portions. For example, the third emission portion EA3 may have a larger area than that of the first emission portion EA1. The third emission portion EA3 that emits blue light may have a larger area than that of the first emission portion EA1 that emits red light. For example, the third emission portion EA3 may have a larger area than that of the second emission portion EA2. The area of the third emission portion EA3 that emits blue light may be larger than the area of the second emission portion EA2 that emits green light. The third emission portion EA3 may be disposed across other emission portions. For example, the third emission portion EA3 may overlap at least portions of the first emission portion EA1 and the second emission portion EA2.

A spacer 530 may be disposed to have a preset distance (or separation distance) from the plurality of sub-pixels SP. For example, the spacer 530 may be spaced apart from the plurality of sub-pixels SP at a set distance and disposed to be surrounded by the plurality of sub-pixels SP. For example, as shown in FIG. 4, four sub-pixels may surround one spacer, but the present disclosure is not limited thereto and the spacer may be composed of 5, 6, 7, and 8 spacers and the like and may be implemented depending on a structure and type of the display device.

The spacer 530 may be disposed substantially in a center of the plurality of sub-pixels emitting at least one same color. For example, the spacer 530 may be disposed in a center of the second emission portions EA2 that emits green light.

The spacer 530 can minimize or reduce damage to the display device 100 from external impacts by cushioning an empty space between the substrate 110 over which an emission element layer 500 (e.g., a light emitting element) is formed and an upper substrate.

Additionally, the spacer 530 can protect the emission element layer 500. For example, when forming the emission element layer 500, a fine metal mask (FMM) can be used. The fine metal mask may sag during processing due to its weight. Accordingly, by placing the spacer 530, the fine metal mask (FMM) and the spacer 530 come into contact with each other, so it is possible to prevent a defect in which the fine metal mask directly contacts the bank 520, deforming or damaging the bank 520.

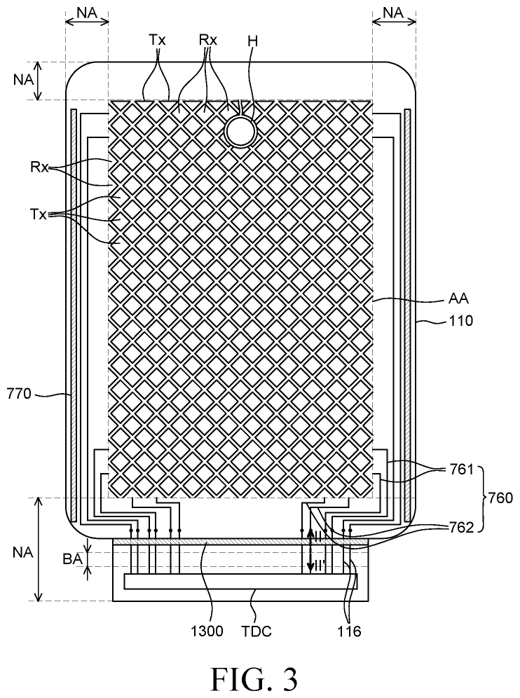

FIG. 3 is a plan view of a touch unit according to an exemplary embodiment of the present disclosure.

Referring to FIG. 3, the touch unit may include first touch blocks Rx and second touch blocks Tx.

At least one first touch blocks Rx and second touch blocks Tx may be disposed in the active area AA of the display device 100.

The first touch block Rx may include at least one first touch electrodes 740_R and at least one first touch connection electrodes 720 as shown in FIG. 5. The second touch block Tx may include at least one second touch electrodes and at least one second touch connection electrodes 740_C.

The at least one first touch blocks Rx extend in a first direction (or X-axis direction). The first touch block Rx may include at least one first touch electrodes 740_R disposed at regular intervals from each other.

The at least one first touch electrodes 740_R may be electrically connected to each other in the first direction (or X-axis direction). For example, the at least one first touch electrodes 740_R disposed in the first direction (or X-axis direction) may be electrically connected to each other by the first touch connection electrode 720. The first touch connection electrode 720 may be disposed on a layer different from that of the first touch electrode 740_R, and the first touch connection electrode 720 and the first touch electrode 740_R can be electrically connected through a hole of a touch insulating layer disposed between the first touch electrode 740_R and the first touch connection electrode 720.

However, the configuration of the touch unit according to the present disclosure is not limited to the above. For example, the touch unit may include a first touch electrode, a second touch electrode and a touch insulating layer therebetween.

Each of the at least one first touch blocks Rx may be spaced apart at a certain interval in a second direction (or Y-axis direction).

The at least one second touch blocks Tx extend in the second direction (or Y-axis direction). The second touch block Tx may include at least one second touch electrodes disposed at a predetermined distance from each other.

The at least one second touch electrodes may be formed continuously without interruption in the second direction (or Y-axis direction). For example, the second touch electrodes disposed in the second direction (or Y-axis direction) may be electrically connected to each other by the second touch connection electrode 740_C.

The second touch electrode and the second touch connection electrode 740_C may be disposed on the same layer.

Each of the at least one second touch blocks Tx may be spaced apart at a certain interval in the first direction (or the X-axis direction).

The first touch blocks Rx and the second touch blocks Tx may be disposed to be spaced apart from each other at a predetermined distance. Accordingly, the first touch blocks Rx and the second touch blocks Tx may be electrically separated or insulated from each other.

The first touch blocks Rx and the second touch blocks Tx may have a metal mesh structure. The first touch electrodes 740_R of the first touch blocks Rx and the second touch electrodes of the second touch blocks Tx may have a metal mesh structure.

The first touch electrodes 740_R, the second touch electrodes, the first touch connection electrodes 720, and the second touch connection electrodes 740_C disposed in the active area AA can be formed in a mesh pattern formed by crossing metal lines with small line widths each other. The mesh pattern may have a diamond shape. Additionally, a shape of the mesh pattern may be quadrangular, pentagonal, hexagonal, circular, or oval, but is not limited thereto.

Openings may be formed inside the mesh pattern of the first touch electrodes 740_R and second touch electrodes. The openings may correspond to the sub-pixels SP. For example, in the openings of the first touch electrodes 740_R and the second touch electrodes, a first thin film transistor 200, a second thin film transistor 300, a storage capacitor 400, and the emission element layer 500 of the display driver DISP may be disposed.

The first touch electrode 740_R, the second touch electrode, the first touch connection electrode 720, and the second touch connection electrode 740_C may be formed not to overlap (e.g., non-overlapping) the emission areas of red (R), green (G), and blue (B) and to overlap the bank 520 formed in the non-emission area. For example, the first touch electrode 740_R, the second touch electrode, the first touch connection electrode 720, and the second touch connection electrode 740_C may be designed and formed with a small line width thickness so that they do not overlap the emission areas of red (R), green (G), and blue (B) but overlap the bank 520 formed in the non-emission area.

In this disclosure, descriptions are made based on that the first touch blocks Rx extend in the first direction (or X-axis direction) and the second touch blocks Tx extend in the second direction (or Y-axis direction), but vice verse. For example, the first touch blocks Rx may extend in the second direction (or Y-axis direction), and the second touch blocks Tx may extend in the first direction (or X-axis direction).

Touch lines 760, a touch driving circuit TDC, and a dummy portion 770 may be disposed in the first non-active area NA1 of the display device 100.

Each of the first touch blocks Rx and the second touch blocks Tx may be electrically connected to the corresponding touch lines 760.

The touch lines 760 may include first touch lines 761 and second touch lines 762. The first touch lines 761 may be electrically connected to the first touch blocks Rx, and the second touch lines 762 may be electrically connected to the second touch blocks Tx.

Each of the first touch blocks Rx and the second touch blocks Tx may be connected to the touch driving circuit TDC disposed in a portion of the first non-active area NA1 by the first touch lines 761 and the second touch lines 762. Each of the first touch blocks Rx and the second touch blocks Tx is connected to the touch driving circuit TDC and can transmit or receive a corresponding signal.

The touch driving circuit TDC may receive a touch detection signal from the first touch block Rx or the first touch electrode 740_R. Additionally, the touch driving circuit TDC may transmit a touch driving signal to the second touch block Tx or the second touch electrode. The touch driving circuit TDC can detect a user's touch using mutual capacitance between the first touch block Rx and the second touch block Tx. For example, when a touch operation is performed on the display device 100, a change in capacitance may occur between the first touch block Rx and the second touch block Tx. The touch driving circuit TDC can detect touch coordinates by detecting this change in capacitance.

The touch lines 760 may be disposed between signal lines of the gate driver 112 and the active area AA.

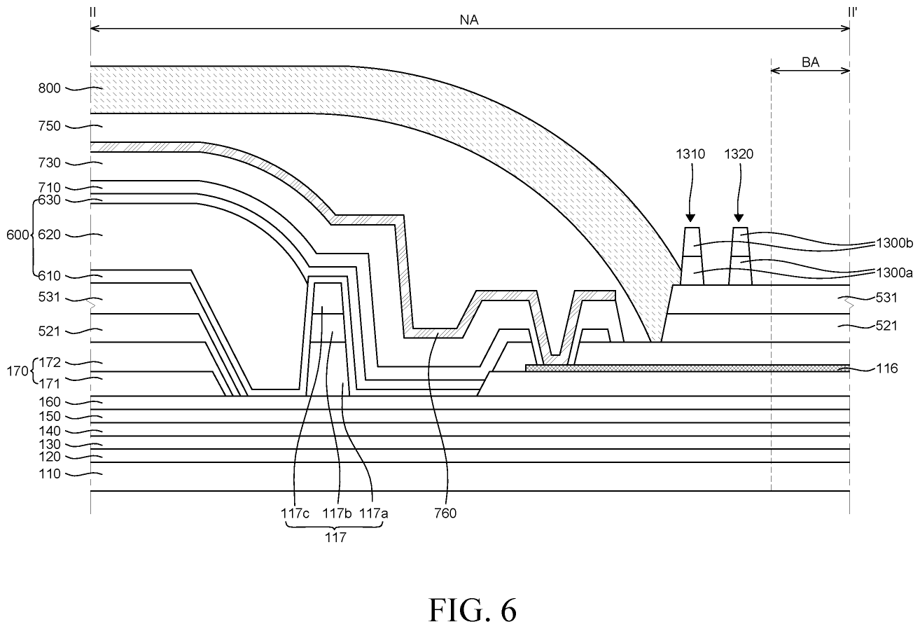

The touch lines 760 may be electrically connected to the touch driving circuit TDC through the connection lines 116. The touch lines 760 and the connection lines 116 may be in contact by etching a portion of the insulating layer or protective layer between the active area AA and the bending area BA. For example, the touch line 760 and the connection line 116 may be in contact between the dam portion 117 and the partition 1300 in the non-active area NA. In one embodiment, the partition 1300 is non-overlapping with the connection (e.g., the contact point) between the connection line 116 and the touch line 760 a shown in FIGS. 6-9.

The dummy portion 770 may be further disposed on the other side of the first non-active area NA1 of the substrate 110. The dummy portion 770 may be disposed between the touch line and the end point (or end) of the substrate 110. For example, the dummy portion 770 may be a touch dummy or a touch dummy portion, but embodiments of the present disclosure are not limited thereto.

The dummy portion 770 is insulated from the touch line and the touch block, and a constant voltage may be applied thereto. The dummy portion 770 can reduce noise caused by the signal line by distributing noise caused by parasitic capacitance formed by the signal line of the gate driver.

A hole H may be further included inside the touch unit 700. A touch block is disposed in the touch unit 700. The touch block can be disposed bypassing the hole H.

Hereinafter, a cross-sectional structure of this disclosure will be described in detail with reference to FIGS. 5 and 6.

FIG. 5 is a cross-sectional view taken along line I-I′ of FIG. 4 according to an exemplary embodiment of the present disclosure. FIG. 5 is a view illustrating a portion of a cross-sectional structure of one sub-pixel SP disposed in the active area shown in FIG. 4. In the sub-pixel SP, the emission element layer 500 for displaying an image and a plurality of the first thin film transistor 200 and second thin film transistor 300 for driving the emission element layer 500 may be disposed.

The substrate 110 may support various components of the display device. The substrate 110 may be formed of glass or a flexible plastic material.

For example, the substrate 110 may be formed of at least one of polyimide (PI), polymethylmethacrylate (PMMA), polyethylene terephthalate (PET), polyethersulfone, and polycarbonate (PC), but is not limited thereto.

When the substrate 110 is formed of polyimide, it can be composed of two polyimide layers. An inorganic film may be further disposed between the two polyimide layers.

It may be referred to as a concept including elements and functional layers formed on the substrate 110, for example, a switching thin film transistor, a driving thin film transistor connected to the switching thin film transistor, an organic emission element connected to the driving thin film transistor, a protective layer, and the like, but the present disclosure is not limited thereto.

A first insulating layer 120 may be disposed on an entirety of the substrate 110. For example, the first insulating layer 120 may be disposed on an entire surface of the substrate 110.

The first insulating layer 120 is formed on the substrate 110 and can block materials inside the substrate 110 from moving to the thin film transistor or a semiconductor layer during a deposition process.

The first insulating layer 120 may be formed of an insulating inorganic material such as silicon nitride (SiNx) or silicon oxide (SiOx), and may be formed of an insulating organic material, but is not limited thereto.

The first insulating layer 120 may be formed of a single layer of silicon nitride (SiNx) or silicon oxide (SiOx) or multiple layers thereof, but embodiments of the present disclosure are not limited thereto. When the first insulating layer 120 is formed of multiple layers, silicon oxide (SiOx) and silicon nitride (SiNx) may be formed alternately, but embodiments of the present disclosure are not limited thereto.

The first insulating layer 120 may be a buffer layer or a first buffer layer, but embodiments of the present disclosure are not limited thereto.

The first insulating layer 120 may be omitted depending on a type and material of the substrate 110, a structure and type of the thin film transistor, and the like.

The first thin film transistor 200 and the second thin film transistor 300 may be disposed on the first insulating layer 120. The first thin film transistor 200 may be a switching thin film transistor, and the second thin film transistor 300 may be a driving thin film transistor, but embodiments of the present disclosure are not limited thereto.

The first thin film transistor 200 may include a first semiconductor layer 210, a first gate electrode 230, a first source electrode 250, and a first drain electrode 270. The second thin film transistor 300 may include a second semiconductor layer 310, a second gate electrode 330, a second source electrode 350, and a second drain electrode 370.

For convenience of explanation, only two thin film transistors among various thin film transistors are shown, but other thin film transistors may also be included in the display device 100. In addition, for convenience of explanation, it is described that the thin film transistor has a top gate structure in which a gate electrode constituting the thin film transistor is located above the semiconductor layer, but it is not limited to the structure. In addition, the thin film transistor may be implemented in another structure such as a bottom gate structure in which the gate electrode is located below the semiconductor layer or a double gate structure in which the gate electrode is located both above and below the semiconductor layer.

The first semiconductor layer 210 of the first thin film transistor 200 and the second semiconductor layer 310 of the second thin film transistor 300 may be disposed on the first insulating layer 120.

The first semiconductor layer 210 and the second semiconductor layer 310 may be formed of a polycrystalline semiconductor. For example, the polycrystalline semiconductor may be formed of low temperature poly silicon (LTPS) with high mobility, but is not limited thereto. When the first semiconductor layer 210 and the second semiconductor layer 310 are formed of the polycrystalline semiconductor, energy consumption is low and reliability is excellent.

Additionally, the first semiconductor layer 210 and the second semiconductor layer 310 may be formed of an oxide semiconductor. For example, it may be formed of any one of IGZO (Indium-gallium-zinc-oxide), IZO (Indium-zinc-oxide), IGTO (Indium-gallium-tin-oxide), and IGO (Indium-gallium-oxide), but is not limited thereto. When the first semiconductor layer 210 and the second semiconductor layer 310 are formed of an oxide semiconductor, an effect of blocking leakage current is excellent, so changes in luminance of the sub-pixels can be minimized during low-speed driving.

When the first semiconductor layer 210 and the second semiconductor layer 310 are formed of a polycrystalline semiconductor or an oxide semiconductor, portions of the first semiconductor layer 210 and the second semiconductor layer 310 may have a conductive region.

The first semiconductor layer 210 and the second semiconductor layer 310 may be formed of amorphous silicon (a-Si) or various organic semiconductor materials such as pentacene, but the present disclosure is not limited thereto.

A second insulating layer 130 may be disposed on an entire area of the substrate 110 on the first semiconductor layer 210 and the second semiconductor layer 310.

The second insulating layer 130 may be disposed between the first semiconductor layer 210 and the first gate electrode 230 to insulate the first semiconductor layer 210 and the first gate electrode 230. The second insulating layer 130 may be disposed between the second semiconductor layer 310 and the second gate electrode 330 to insulate the second semiconductor layer 310 and the second gate electrode 330.

The second insulating layer 130 may be formed of an insulating inorganic material such as silicon nitride (SiNx) or silicon oxide (SiOx), and may be formed of an insulating organic material, but is not limited thereto.

The second insulating layer 130 may have holes to electrically connect each of the first source electrode 250 and the first drain electrode 270 to the first semiconductor layer 210. The second insulating layer 130 may have holes to electrically connect each of the second source electrode 350 and the second drain electrode 370 to the second semiconductor layer 310.

The first gate electrode 230 of the first thin film transistor 200 and the second gate electrode 330 of the second thin film transistor 300 may be disposed on the second insulating layer 130. The first gate electrode 230 may be disposed to overlap the first semiconductor layer 210. The second gate electrode 330 may be disposed to overlap the second semiconductor layer 310.

The storage capacitor 400 may be disposed on the second insulating layer 130. The storage capacitor 400 may include a first capacitor electrode 410 and a second capacitor electrode 420. The storage capacitor 400 can store a data voltage applied through the data line for a certain period of time and then provide it to a first electrode 510.

The first capacitor electrode 410 of the storage capacitor 400 may be disposed on the second insulating layer 130.

The first gate electrode 230, the second gate electrode 330, and the first capacitor electrode 410 may be disposed on the same layer. For example, the first gate electrode 230, the second gate electrode 330, and the first capacitor electrode 410 may be disposed on the second insulating layer 130.

The first gate electrode 230, the second gate electrode 330, and the first capacitor electrode 410 may be formed through the same process.

The first gate electrode 230, the second gate electrode 330, and the first capacitor electrode 410 may be formed in a single layer or multiple layers formed of any one of molybdenum (Mo), copper (Cu), titanium (Ti), aluminum (Al), chromium (Cr), gold (Au), nickel (Ni), neodymium (Nd), tungsten (W), gold (Au), and a transparent conductive oxide (TCO) or an alloy thereof, but the present disclosure is not limited thereto.

A third insulating layer 140 may be disposed on the entire area of the substrate 110 on the first gate electrode 230, the second gate electrode 330, and the first capacitor electrode 410.

The third insulating layer 140 is disposed between the first gate electrode 230, and the first source electrode 250 and the first drain electrode 270, and may insulate the first gate electrode 230 from the first source electrode 250 and the first drain electrode 270. The third insulating layer 140 may be disposed between the second gate electrode 330, and the second source electrode 350 and the second drain electrode 370, and insulate the second gate electrode 330 from and the second source electrode 350 and the second drain electrode 370.

The third insulating layer 140 may have holes to electrically connect each of the first source electrode 250 and the first drain electrode 270 to the first semiconductor layer 210. The third insulating layer 140 may have holes to electrically connect each of the second source electrode 350 and the second drain electrode 370 to the second semiconductor layer 310.

The third insulating layer 140 may be formed of an insulating inorganic material such as silicon nitride (SiNx) or silicon oxide (SiOx), and may be formed of an insulating organic material, but is not limited thereto.

The second capacitor electrode 420 of the storage capacitor 400 may be disposed on the third insulating layer 140. The second capacitor electrode 420 may be disposed to overlap the first capacitor electrode 410.

The second capacitor electrode 420 may be formed in a single layer or multiple layers formed of any one of molybdenum (Mo), copper (Cu), titanium (Ti), aluminum (Al), chromium (Cr), gold (Au), nickel (Ni), neodymium (Nd), tungsten (W), gold (Au), and a transparent conductive oxide (TCO) or an alloy thereof, but the present disclosure is not limited thereto.

A fourth insulating layer 150 may be disposed on the entire area of the substrate 110 on the second capacitor electrode 420.

The fourth insulating layer 150 may be disposed between the first gate electrode 230, and the first source electrode 250 and the first drain electrode 270, and insulate the first gate electrode 230 from the first source electrode 250 and the first drain electrode 270. The fourth insulating layer 150 may be disposed between the second gate electrode 330, and the second source electrode 350 and the second drain electrode 370, and insulate the second gate electrode 330 from the second source electrode 350 and the second drain electrode 370.

The fourth insulating layer 150 may have holes to electrically connect each of the first source electrode 250 and the first drain electrode 270 to the first semiconductor layer 210. The fourth insulating layer 150 may have holes to electrically connect each of the second source electrode 350 and the second drain electrode 370 to the second semiconductor layer 310.

The fourth insulating layer 150 may be formed of an insulating inorganic material such as silicon nitride (SiNx) or silicon oxide (SiOx), or may be formed of an insulating organic material, but is not limited thereto.

The first source electrode 250 and the first drain electrode 270 may be disposed on the fourth insulating layer 150. The second source electrode 350 and the second drain electrode 370 may be disposed on the fourth insulating layer 150.

Each of the first source electrode 250 and the first drain electrode 270 may be electrically connected to the first semiconductor layer 210 through holes in the second insulating layer 130, the third insulating layer 140, and the fourth insulating layer 150. Each of the second source electrode 350 and the second drain electrode 370 may be electrically connected to the second semiconductor layer 310 through holes in the second insulating layer 130, the third insulating layer 140, and the fourth insulating layer 150.

The first source electrode 250, the first drain electrode 270, the second source electrode 350, and the second drain electrode 370 may be formed in a single layer or multiple layers formed of any one of molybdenum (Mo), copper (Cu), titanium (Ti), aluminum (Al), chromium (Cr), gold (Au), nickel (Ni), neodymium (Nd), tungsten (W), gold (Au), and a transparent conductive oxide (TCO) or an alloy thereof, but the present disclosure is not limited thereto. For example, the first source electrode 250, the first drain electrode 270, the second source electrode 350, and the second drain electrode 370 may be formed of a three-layer structure of titanium (Ti)/aluminum (Al)/titanium (Ti), which are conductive metal materials, but the present disclosure is not limited thereto.

A fifth insulating layer 160 may be disposed on the entire area of the substrate 110 on the first source electrode 250, the first drain electrode 270, the second source electrode 350, and the second drain electrode 370.

The fifth insulating layer 160 may protect the first thin film transistor 200 and the second thin film transistor 300. The fifth insulating layer 160 may be formed of an insulating inorganic material such as silicon nitride (SiNx) or silicon oxide (SiOx), or may be formed of an insulating organic material, but is not limited thereto.

The fifth insulating layer 160 may have a hole to electrically connect the second thin film transistor 300 and a connection electrode 180 or the first electrode 510. The fifth insulating layer 160 may be omitted depending on the structure and type of the thin film transistor.

A protective layer 170 may be disposed on the fifth insulating layer 160. For example, the protective layer 170 may be an insulating layer or a planarization layer, but embodiments of the present disclosure are not limited thereto. The protective layer 170 protects the thin film transistor disposed below the protective layer 170 and can alleviate or flatten steps caused by various patterns. For example, the protective layer 170 may insulate components disposed above and below the protective layer 170. For example, the protective layer 170 may be disposed in a single layer, but considering an arrangement of electrodes, it may be disposed in two or more layers, that is, a plurality of layers.

As the display device 100 develops to have a higher resolution, the number of various signal lines increases, making it difficult to arrange all lines on one layer while ensuring a minimum spacing therebetween, so additional layers may be configured. The additional layer may allow a margin for line arrangement, so that an arrangement design of lines/electrodes can be further facilitated. If a dielectric material is used as a multilayer planarization layer, the protective layer 170 may be used to form capacitance between metal layers.

When the protective layer 170 is disposed in two layers, it may include a first protective layer 171 and a second protective layer 172. For example, the first protective layer 171 may be a sixth insulating layer, but embodiments of the present disclosure are not limited thereto. For example, the second protective layer 172 may be a seventh insulating layer, but embodiments of the present disclosure are not limited thereto. For example, a hole may be formed in the first protective layer 171, and the connection electrode 180 may be disposed within the hole. The second protective layer 172 having a hole may be disposed on the first protective layer 171 and the connection electrode 180. The first electrode 510 may be disposed in the hole of the second protective layer 172. Accordingly, the first thin film transistor 300 and the first electrode 510 can be electrically connected through the connection electrode 180.

One end (or one portion or side) of the connection electrode 180 may be connected to the second thin film transistor 300, and the other end (or another portion or side) of the connection electrode 180 may be connected to the first electrode 510.

The connection electrode 180 may be further disposed on the first protective layer 171.

The connection electrode 180 may be formed in a single layer or multiple layers formed of any one of molybdenum (Mo), copper (Cu), titanium (Ti), aluminum (Al), chromium (Cr), gold (Au), nickel (Ni), neodymium (Nd), tungsten (W), gold (Au), and a transparent conductive oxide (TCO) or an alloy thereof, but the present disclosure is not limited thereto. For example, the connection electrode 180 may have a three-layer structure of titanium (Ti)/aluminum (Al)/titanium (Ti) formed of conductive metal materials.

The connection electrode 180 may be a first connection electrode, and embodiments of the present disclosure are not limited thereto. The connection electrode 180 may be omitted based on a structure and type of the display device 100.

The second protective layer 172 may be disposed on the first protective layer 171 and the connection electrode 180.

The first protective layer 171 and the second protective layer 172 may be formed of at least one material of organic insulating materials such as BCB (benzo cyclobutene), acryl resin, epoxy resin, phenolic resin, polyamide resin, or polyimide resin, but the present disclosure is not limited thereto.

The protective layer 170 of the display device 100 may be disposed in three layers considering the arrangement of the electrodes, but exemplary embodiments of the present disclosure are not limited thereto. Accordingly, additional connection electrodes may be further disposed.

The emission element layer 500 may be disposed on the protective layer 170 or the second protective layer 172. The emission element layer 500 may include the first electrode 510, an organic layer 540, and a second electrode 550.

The first electrode 510 may be disposed on the protective layer 170. The first electrode 510 supplies holes to the organic layer 540 and may be formed of a conductive material with a high work function. The first electrode may be an anode electrode, and embodiments of the present disclosure are not limited thereto.

When the display device 100 is a top emission type, the first electrode 510 is a reflective electrode that reflects light and may be disposed using an opaque conductive material. The first electrode 510 may be formed of at least one of silver (Ag), aluminum (Al), gold (Au), molybdenum (Mo), tungsten (W), chromium (Cr), or alloys thereof, but embodiments of the present disclosure are not limited thereto. For example, the first electrode 510 may have a three-layer structure of silver (Ag)/lead (Pd)/copper (Cu), but is not limited thereto. Alternatively, the first electrode 510 may further include a transparent conductive material layer with a high work function, such as indium-tin-oxide (ITO).

When the display device 100 is a bottom emission type, the first electrode 510 may be disposed using a transparent conductive material that transmits light. For example, the first electrode 510 may be formed of at least one of indium tin oxide (ITO) and indium zinc oxide (IZO), but embodiments of the present disclosure are not limited thereto. The bank 520 may be disposed on the first electrode 510 and the protective layer 170.

The bank 520 can distinguish the plurality of sub-pixels SP, minimize or at least reduce light blurring, and prevent or at least reduce color mixing that occurs at various viewing angles. The bank 520 may define (or divide) the emission portion that emits light and the non-emission portion that does not emit light, and the bank 520 may be disposed in the non-emission portion. The bank 520 may have a bank hole exposing the emission portion and the first electrode 510.

The bank 520 may be formed of at least one material among an inorganic insulating material such as silicon nitride (SiNx) or silicon oxide (SiOx), an organic insulating material such as BCB (benzo cyclobutene), acryl resin, epoxy resin, phenolic resin, polyamide resin, or polyimide resin, or a photosensitive agent containing black pigment, but is not limited thereto.

The bank 520 may be black (or black) or colored. For example, when the bank 520 includes a black material, it is possible to prevent external light, internal reflected light, and/or scattered light scattered from a side of the first electrode 510 from being incident on the thin film transistor, and a decrease in luminance of the display device can be reduced. The bank 520 may be disposed to cover an end (or a partial area) of the first electrode 510.

At least one spacer 530 may be disposed on the bank 520.

The spacer 530 can prevent or at least reduce damage to the organic layer 540 during processing and minimize or at least reduce damage to the display device 100 from external impacts.

The spacer 530 may be formed of the same material as the bank 520, may be formed simultaneously with the bank 520, or may be formed through a separate process. For example, the spacer 530 may be transparent, black (or black), or colored. Alternatively, the spacer 530 may include a transparent material, a black material, or a colored material.

A thickness of the spacer 530 may be equal to or greater than a thickness of the bank 520, and the thickness of the spacer 530 may be 1 μm to 2 μm, but embodiments of the present disclosure are not limited thereto.

The organic layer 540 may be disposed on the first electrode 510 and the bank 520. The organic layer 540 may include an emission layer EML for emitting light of a specific color in each of the plurality of sub-pixels SP. The emission layer may be a layer that emits light. For example, holes generated in the first electrode 510 and electrons generated in the second electrode 550 may be injected into the emitting layer. The holes and electrons injected into the emission layer can combine to generate excitons. Light can be generated when the generated excitons fall from an excited state to a ground state.

For example, the emission layer may include one of a red emission layer that emits red light, a green emission layer that emits green light, a blue emission layer that emits blue light, and a white emission layer. When the organic layer 540 includes a white emission layer, a color filter may be disposed on the organic layer 540 to convert white light from the white emission layer into light of another color. In addition, the organic layer 540 may further include, in addition to the emission layer, a hole injection layer HIL, a hole transport layer HTL, an electron blocking layer EBL, a hole blocking layer HBL, an electron transport layer ETL, an electron injection layer EIL, and the like, but the present disclosure is not limited thereto.

The emission layer of the organic layer 540 may be disposed in each of the plurality of sub-pixels SP, and the hole injection layer HIL, the hole transport layer HTL, the electron blocking layer EBL, the hole blocking layer HBL, the electron transport layer ETL, and the electron injection layer EIL may be disposed in an entirety of the active area AA.

The organic layer 540 of the display device according to the present disclosure may be an emission unit. At least one emission unit may be disposed. For example, a stack structure can be configured by stacking a plurality of emission units between the first electrode 510 and the second electrode 550. In this case, a charge generation layer may be further disposed between the plurality of emission units. The plurality of emission units may be disposed for each of the sub-pixels SP.

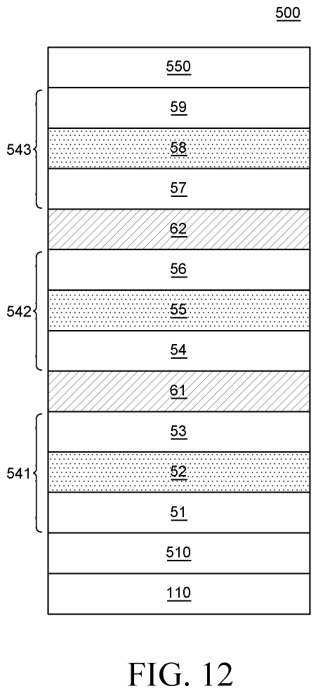

The emission unit will be described in detail later in FIG. 12.

The second electrode 550 may be disposed on the organic layer 540. The second electrode 550 supplies electrons to the organic layer 540 and may be formed of a conductive material with a low work function. The second electrode may be a cathode electrode, and embodiments of the present disclosure are not limited thereto.

When the display device 100 is a top emission type, the second electrode 550 may be disposed using a transparent conductive material that transmits light. For example, it may be formed of at least one of indium tin oxide (ITO) and indium zinc oxide (IZO), but is not limited thereto. Additionally, the second electrode 550 may be disposed using a translucent conductive material that transmits light. For example, the second electrode 550 may be formed of at least one of alloys such as LiF/Al, CsF/Al, Mg:Ag, Ca/Ag, Ca:Ag, LiF/Mg:Ag, LiF/Ca/Ag, and LiF/Ca:Ag, but is not limited thereto.

When the display device 100 is a bottom emission type, the second electrode 550 is a reflective electrode that reflects light and may be disposed using an opaque conductive material. For example, the second electrode 550 may be formed of at least one of silver (Ag), aluminum (Al), gold (Au), molybdenum (Mo), tungsten (W), chromium (Cr), or alloys thereof.

The encapsulation layer 600 may be disposed on the second electrode 550. The encapsulation layer 600 can protect the organic layer 540 from external moisture, oxygen, or foreign materials. For example, in order to prevent oxidations of an emission material and an electrode material, an infiltration of oxygen and moisture from the outside can be prevented.

In one embodiment, the encapsulation layer 600 extends from the active area AA to the non-active area NA. At least a portion of the encapsulation layer 600 contacts the dam in the non-active area NA. The encapsulation layer 600 may include a first encapsulation layer 610, a second encapsulation layer 620, and a third encapsulation layer 630 that block penetration of moisture or oxygen. The first encapsulation layer 610, the second encapsulation layer 620, and the third encapsulation layer 630 may have a structure in which they are alternately stacked, but exemplary embodiments of the present disclosure are not limited thereto.

The encapsulation layer 600 may be formed of a transparent material so that light emitted from the emission layer can be transmitted.

The first encapsulation layer 610 and the third encapsulation layer 630 may be formed of at least one inorganic material of silicon nitride (SiNx), silicon oxide (SiOx), or aluminum oxide (AlyOz), but are not limited thereto. The first encapsulation layer 610 and the third encapsulation layer 630 may be formed using a vacuum deposition method such as chemical vapor deposition (CVD) or atomic layer deposition (ALD), but are not limited thereto.

The first encapsulation layer 610 and the third encapsulation layer 630 may be formed of at least two or more layers. For example, the first encapsulation layer 610 may have a three-layer structure of silicon oxide (SiOx)/silicon nitride (SiNx)/silicon oxide (SiOx), but is not limited thereto. Alternatively, the first encapsulation layer 610 may have a four-layer structure of silicon oxide (SiOx)/silicon nitride (SiNx)/silicon oxide (SiOx)/silicon oxide (SiOx), but is not limited thereto.

The second encapsulation layer 620 can cover foreign materials or particles that may occur during a manufacturing process. Additionally, the second encapsulation layer 620 may flatten a surface of the first encapsulation layer 610. For example, the second encapsulation layer 620 may be a particle cover layer, but the term is not limited thereto.

The second encapsulation layer 620 is an organic material, for example, a polymer such as silicon oxycarbon (SiOCz) epoxy, polyimide, polyethylene, or acrylate, but is not limited thereto.

The second encapsulation layer 620 may be formed of a heat-curable material or a photocurable material that is cured by heat or light.

The second encapsulation layer 620 may be formed in various ways, such as inkjet coating or slit coating. For example, the second encapsulation layer 620 may be formed on the first encapsulation layer 610 by spraying or dropping a liquid organic material onto the active area AA using an inkjet device or a nozzle coating device on the substrate 110 on which the first encapsulation layer 610 is formed. As a spray nozzle moves over an application area (or as the nozzle is fixed and an object moves), an organic material in a fluid state may be formed in the application area.

Since a material constituting the second protective layer 620 has low viscosity characteristics, it may be in a high-density liquid-like state until it is hardened. In order to solve a defect in which the second protective layer 620 spreads (or flows) into the first non-active area NA1, the dam portion 117 may be disposed between the active area AA and the first non-active area NA1.

The dam portion 117 will be described in detail later in FIG. 6.

The touch unit 700 may be disposed on the encapsulation layer 600.

The touch unit 700 may include the first touch electrode 740_R, the first touch connection electrode 720, the second touch electrode, and the second touch connection electrode 740_C.

A portion of the first touch electrode 740_R, the first touch connection electrode 720, the second touch electrode, and the second touch connection electrode 740_C may be disposed to overlap the bank 520.

The first touch electrode 740_R, the second touch electrode, the first touch connection electrode 720, and the second touch connection electrode 740_C may be formed in a mesh pattern in which metal lines with small line widths intersect each other. The mesh pattern may have a diamond shape. Additionally, the shape of the mesh pattern may be quadrangular, pentagonal, hexagonal, circular, or oval, but is not limited thereto.

The first touch electrode 740_R, the second touch electrode, the first touch connection electrode 720, and the second touch connection electrode 740_C may be disposed using an opaque conductive material with a low resistance. For example, they may be formed in a single layer or multiple layers formed of any one of molybdenum (Mo), copper (Cu), titanium (Ti), aluminum (Al), chromium (Cr), gold (Au), nickel (Ni), neodymium (Nd), tungsten (W), gold (Au), and a transparent conductive oxide (TCO) or an alloy thereof, but the present disclosure is not limited thereto. For example, the first touch electrode 740_R, the second touch electrode, the first touch connection electrode 720, and the second touch connection electrode 740_C may be formed in a three-layer structure of titanium (Ti)/aluminum (Al)/titanium (Ti), which are conductive metal materials, but the present disclosure is not limited thereto.

The first touch electrode 740_R, the second touch electrode, the first touch connection electrode 720, and the second touch connection electrode 740_C may be formed of the same materials as the first source electrode 250, the first drain electrode 270, the second source electrode 350, and the second drain electrode 370, but exemplary embodiments of the present disclosure are not limited thereto.

A buffer layer 710 may be disposed on the encapsulation layer 600. The buffer layer 710 may block chemical solutions (such as developer or etchant) used during a manufacturing process of the touch unit 700 or moisture from the outside from penetrating into the emission element layer 500 containing an organic material. In addition, it is possible to prevent a defect in which a plurality of touch sensor metals disposed on an upper part of the buffer layer 710 are disconnected due to external impacts, and to block interference signals that may occur when the touch unit 700 is driven. For example, the buffer layer 710 may be a touch buffer layer, a second buffer layer, or an eighth insulating layer, but embodiments of the present disclosure are not limited thereto.

The buffer layer 710 may be formed of at least one material of an inorganic insulating material such as silicon nitride (SiNx) or silicon oxide (SiOx) or an organic insulating material such as BCB (benzo cyclobutene), acryl resin, epoxy resin, phenolic resin, polyamide resin, or polyimide resin, but is not limited thereto.

The first touch connection electrode 720 may be disposed on the buffer layer 710.

For example, the first touch connection electrode 720 may be disposed between the first touch electrodes 740_R adjacent in the first direction (or the X-axis direction). The first touch connection electrode 720 may electrically connect a plurality of the first touch electrodes 740_R disposed adjacent and spaced apart in the first direction (or the X-axis direction), but is not limited thereto.

The first touch connection electrodes 720 may be disposed to overlap the second touch connection electrodes 740_C connecting the second touch electrodes adjacent in the second direction (or Y-axis direction). Since the first touch connection electrode 720 and the second touch connection electrode 740_C are formed in different layers, they may be electrically insulated. For example, the first touch connection electrode 720 may be a connection electrode or a second connection electrode, but embodiments of the present disclosure are not limited thereto. For example, the second touch connection electrode 740_C may be a third connection electrode, but embodiments of the present disclosure are not limited thereto.

An insulating layer 730 may be disposed on the buffer layer 710 and the first touch connection electrode 720. For example, the insulating layer 730 may be a touch insulating layer or a ninth insulating layer, but embodiments of the present disclosure are not limited thereto.

The insulating layer 730 may include a hole to electrically connect the first touch electrode 740_R and the first touch connection electrode 720. For example, the insulating layer 730 may electrically insulate the second touch electrode and the second touch connection electrode 740_C. For example, the insulating layer 730 may be formed of an organic material, for example, a polymer such as silicon oxycarbon (SiOCz) epoxy, polyimide, polyethylene, or acrylate, but is not limited thereto. The insulating layer 730 may be formed of a heat-curable material or a photocurable material that is cured by heat or light.

When the insulating layer 730 is formed of an inorganic material, the insulating layer 730 is disposed along sharp steps and bends of various components disposed below the insulating layer 730. Therefore, the sharp steps and bends are not covered, which may cause a defect in which some of internal components of the display device are visible from the outside. This reduces aesthetics for users because they recognize those as defects such as stains. Additionally, an insulating layer formed of an inorganic material is less effective in blocking moisture and oxygen penetrating from the outside of the display device than an insulating layer formed of an organic material. Alternatively, it cannot cover foreign materials or particles that may occur during a manufacturing process. In addition, when the insulating layer 730 is formed of an organic material, it is possible to prevent a defect in which cracks and disconnections in lines are caused by mechanical stress in a bending area during or after a bending process of a plate during the manufacturing process of the display device including the bending area.

The first touch electrode 740_R, the second touch electrode, and the second touch connection electrode 740_C may be disposed on the insulating layer 730.

The first touch electrode 740_R and the second touch electrode may be disposed to be spaced apart from each other at a predetermined distance. The at least one first touch electrodes 740_R adjacent in the first direction (or X-axis direction) may be formed to be spaced apart from each other. The at least one first touch electrodes 740_R adjacent in the first direction (or X-axis direction) may be connected to the first touch connection electrodes 720 disposed between the plurality of first touch electrodes 740_R. For example, the plurality of first touch electrodes 740_R adjacent to each other may be connected to the first touch connection electrode 720 through a hole in the insulating layer 730.

The second touch electrodes adjacent to each other in the second direction (or Y-axis direction) may be connected by the second touch connection electrode 740_C. The second touch electrodes and the second touch connection electrode 740_C may be formed on the same layer. For example, the second touch connection electrode 740_C may be disposed between a plurality of the second touch electrodes on the same layer as the second touch electrodes. The second touch connection electrode 740_C may be formed to extend from the second touch electrode.

The first touch electrode 740_R, the second touch electrode, and the second touch connection electrode 740_C may be formed through the same process.

A protective layer 750 may be disposed on the first touch electrode 740_R, the second touch electrode, and the second touch connection electrode 740_C. Thus, the protective layer 750 is between the cover layer 800 and the first touch electrode and the second touch electrode. For example, the protective layer 750 may be a planarization layer, a touch planarization layer, a tenth insulating layer, or a third protective layer, but embodiments of the present disclosure are not limited thereto.

The touch driving circuit may receive a touch detection signal from the first touch electrode 740_R. Additionally, the touch driving circuit may transmit a touch driving signal from the second touch electrode. The touch driving circuit may detect a user's touch using mutual capacitance between the plurality of first touch electrodes 740_R and the second touch electrodes. For example, when a touch operation is performed on the display device 100, a change in capacitance may occur between the first touch electrode 740_R and the second touch electrode. The touch driving circuit can detect touch coordinates by detecting this change in capacitance.

The cover layer 800 may be disposed on the protective layer 750.

The cover layer 800 may additionally planarize an area that is not partially planarized by the protective layer 750. Alternatively, the cover layer 800 can effectively block moisture and oxygen flowing in from outside the display device. The cover layer 800 may be a fourth encapsulation layer, and embodiments of the present disclosure are not limited thereto.

The cover layer 800 may be an organic material, for example, a polymer such as silicon oxycarbon (SiOCz) epoxy, polyimide, polyethylene, or acrylate, but is not limited thereto. The cover layer 800 may be formed of a heat-curable material or a photocurable material that is cured by heat or light.

The cover layer 800 may be formed of the same material as that of the second encapsulation layer 620.

The cover layer 800 may be formed in various ways, such as inkjet coating or slit coating. For example, the cover layer 800 may be formed on the protective layer 750 by spraying or dropping a liquid organic material onto the active area AA using an inkjet device or a nozzle coating device on the substrate 110 on which the protective layer 750 is formed. As a spray nozzle moves over an application area (or as the nozzle is fixed and an object moves), an organic material in a fluid state may be formed in the application area.

Since a material constituting the cover layer 800 has low viscosity characteristics, it may be in a high-density liquid-like state until it is hardened. In order to solve a defect in which the cover layer 800 spreads (or flows) into the bending area BA, the partition 1300 may be disposed in the non-active area adjacent to the bending area. The dam portion 117 will be described in detail later in FIG. 6.

Hereinafter, the partition will be described in detail with reference to FIG. 6

FIG. 6 is a cross-sectional view taken along line II-II′ of FIG. 3 according to an exemplary embodiment of the present disclosure. FIG. 6 shows the first non-active area NA1 indicating a portion of the bending area BA.

Referring to FIG. 6, the partition 1300 may be disposed adjacent to a start portion of the bending area BA such that the partition 1300 is between the bending area BA and the dam 117 in the non-active area NA.

In a portion adjacent to the active area AA, a plurality of insulating layers, the protective layer, the encapsulation layer, and the cover layer disposed in the active area AA may be extended to the first non-active area NA1.

The first insulating layer 120, the second insulating layer 130, the third insulating layer 140, the fourth insulating layer 150, the fifth insulating layer 160, the first protective layer 171, the second protective layer 172, a fourth protective layer 521, a fifth protective layer 531, the first encapsulation layer 610, the second encapsulation layer 620, the third encapsulation layer 630, the buffer layer 710, the insulating layer 730, a third protective layer 750, and the cover layer 800 may be sequentially disposed on the substrate 110.

The fourth protective layer 521 may be formed of the same material as the bank 520 of the active area AA, may be formed simultaneously with the bank 520, or may be formed in a separate process. The fourth protective layer 521 may be formed of at least one material among an inorganic insulating material such as silicon nitride (SiNx) or silicon oxide (SiOx), an organic insulating material such as BCB (benzo cyclobutene), acryl resin, epoxy resin, phenolic resin, polyamide resin, or polyimide resin, or a photosensitive agent containing black pigment, but is not limited thereto. The fourth protective layer 521 may be transparent, black, or colored.

The fifth protective layer 531 may be formed of the same material as the spacer 530 in the active area AA, may be formed simultaneously with the spacer 530, or may be formed in a separate process. The fifth protective layer 531 may be formed of at least one material among an inorganic insulating material such as silicon nitride (SiNx) or silicon oxide (SiOx), an organic insulating material such as BCB (benzo cyclobutene), acryl resin, epoxy resin, phenolic resin, polyamide resin, or polyimide resin, or a photosensitive agent containing black pigment, but is not limited thereto. The fifth protective layer 531 may be transparent, black or colored.

The dam portion 117 may be disposed in a portion of the first non-active area NA1 by etching the protective layer. For example, the first protective layer 171, the second protective layer 172, the fourth protective layer 521, and the fifth protective layer 531 are etched, and the dam portion 117 may be disposed on the insulating layer or the fifth insulating layer 160.

The dam portion 117 can prevent the second encapsulation layer 620 formed of an organic material from overflowing into a driving element during a process before it is hardened. The second encapsulation layer 620 may be in contact with the dam portion 117.

One dam portion 117 or a plurality of dam portions 117 may be configured, and when the plurality of dam portions 117 are configured, the second encapsulation layer 620 may be partially formed between the plurality of dam portions.

The dam portion 117 may be disposed in multiple layers using at least one material. For example, when the dam portion 117 is formed in multiple layers, the dam portion 117 may include a first dam portion 117a, a second dam portion 117b, and a third dam portion 117c.

The first dam portion 117a may be formed of the same material as the second protective layer 172, may be formed simultaneously with the spacer 530, or may be formed in a separate process.

The second dam portion 117b may be formed of the same material as the bank 520 and/or the fourth protective layer 521, may be formed simultaneously with the bank 520 and/or the fourth protective layer 521, or can be formed in a separate process.

The third dam portion 117c may be formed of the same material as the spacer 530 and/or the fifth protective layer 531, may be formed simultaneously with the spacer 530 and/or the fifth protective layer 531, or can be formed in a separate process.

The fourth protective layer 521 and the fifth protective layer 531 may be formed simultaneously, but are not limited thereto.

The encapsulation layer 600 may be disposed on the substrate 110 on which the dam portion 117 is disposed. The first encapsulation layer 610 may be disposed on the insulating layer, the protective layer, and/or the dam portion 117 disposed below the first encapsulation layer 610, may cover the dam portion 117, and may extend to the bending area BA.

The second encapsulation layer 620 may be disposed on the first encapsulation layer 610, and the second encapsulation layer 620 may be in contact with the dam portion 117.

The third encapsulation layer 630 may be disposed on the second encapsulation layer 620 and the dam portion 117. The third encapsulation layer 630 may be disposed on the insulating layer, the protective layer, and/or the dam portion 117 disposed below the third encapsulation layer 630, may cover the first encapsulation layer 610 and the dam portion 117, may extend to the bending area BA, and the first encapsulation layer 610 and the third encapsulation layer 630 may be in contact with each other.

On the encapsulation layer 600, the touch line 760 that is electrically connected to the touch driving circuit TDC and the first touch block Rx and the second touch block Tx of the touch unit 700 to transmit or receive a signal may be disposed.

The touch line 760 may be electrically connected to the touch driving circuit TDC through the connection line 116. The touch line 760 and the connection line 116 may be in contact by etching a portion of the insulating layer or protective layer between the active area AA and the bending area BA. For example, the touch line 760 and the connection line 116 may be in contact between the dam portion 117 and the partition 1300.

The third protective layer 750 may be disposed on the touch line 760.

According to an exemplary embodiment of the present disclosure, since the insulating layer 730 is formed of an organic material, the third protective layer 750 formed of an organic material may be omitted.

In one embodiment, the cover layer 800 may be disposed on the third protective layer 750 and extends past an end of the touch line 760 in the non-active area. Since a material constituting the cover layer 800 has low viscosity characteristics, it may be in a high-density liquid-like state until hardened. In order to solve a defect in which the cover layer 800 spreads (or flows) into the bending area BA, the partition 1300 may be disposed in the non-active area adjacent to the bending area. The cover layer may cover the touch unit and the touch line.

The partition 1300 may be disposed between the dam portion 117 and the bending area BA and may be disposed on the fifth protective layer 531 as shown in the cross-section view in FIG. 6. The partition 1300 is disposed on the dam portion 117 and may be disposed in a portion of the bending area BA to control a flow of the cover layer 800 containing an organic material. As shown in FIG. 6, the end of the cover layer 800 contacts the partition 1300 in the non-active area NA to prevent the cover layer 800 from flowing into the bending area BA.

At least one partition 1300 or a plurality of partitions 1300 may be configured. When the plurality of partitions 1300 are configured, the partitions 1300 may include a first partition 1310 and a second partition 1320. The cover layer 800 may be partially formed between the first partition 1310 and the second partition 1320.

The partition 1300 may be disposed in multiple layers using at least one material. For example, when the partition 1300 is formed in multiple layers, the first partition 1310 and the second partition 1320 may include a first partition layer 1300a and a second partition layer 1300b on the first partition layer 1300a.

The first partition layer 1300a may be formed of the same material as the insulating layer 730. The first partition layer 1300a may be formed simultaneously with the insulating layer 730, or may be formed in a separate process.

The second partition layer 1300b may be further disposed on the first partition layer 1300a. The second partition layer 1300b may be formed of the same material as the third protective layer 750 or the touch planarization layer 750. The second partition layer 1300b may be formed simultaneously with the third protective layer 750 or the touch planarization layer 750, or may be formed in a separate process.

Since the display device 100 includes the cover layer 800 and the partition 1300, it is possible to prevent a defect in which cracks and disconnections in lines are caused by mechanical stress in a bending area during or after a bending process of the substrate 110.

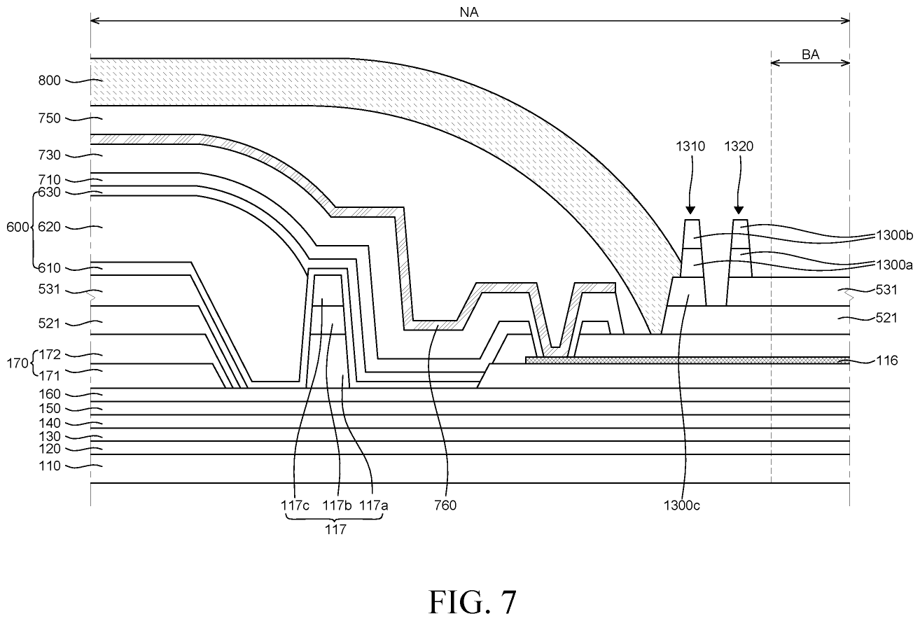

Hereinafter, other embodiments of the present disclosure will be described in detail with reference to FIGS. 7, 8, and 9.

FIGS. 7, 8, and 9 are substantially identical to the display device of FIG. 6 except for a configuration of the partition 1300, so duplicate descriptions will be omitted.

FIG. 7 is a cross-sectional view of a display device according to another exemplary embodiment of the present disclosure.

Referring to FIG. 7, the partition 1300 may further include a third partition layer 1300c disposed below the first partition layer 1300a such that the third partition layer 1300c overlaps the first partition layer 1300a. The third partition layer 1300c may be formed of the same material as that of the spacer 530 or the fifth protective layer 531. The third partition layer 1300c may be formed simultaneously with the spacer 530 or the fifth protective layer 531, or may be formed in a separate process. Although FIG. 7 shows that the third partition layer 1300c is one layer, it is not limited thereto and may be configured in two or more layers, that is, a plurality of layers. For example, the third partition layer 1300c may be formed of the same material as that of the bank 520 or the second protective layer 172. The third partition layer 1300c may be formed simultaneously with the spacer 530, the bank 520, or the second protective layer 172, or may be formed in a separate process. For another example, the third partition layer 1300c may be formed of the same material as that of the fourth protective layer 521, the fifth protective layer 531, or the second protective layer 172. The third partition layer 1300c may be formed simultaneously with the fourth protective layer 521, the fifth protective layer 531, or the second protective layer 172, or may be formed in a separate process.

The third partition layer 1300c can be formed by etching a portion of the fourth protective layer 521, the fifth protective layer 531, or the second protective layer 172. For example, when forming the spacer 530, the bank 520, and a hole in the second protective layer 172 in the active area AA, process conditions may be adjusted, so that the fourth protective layer 521, the fifth protective layer 531, or the second protective layer 172 disposed in the first non-active area NA1 may be etched.

The third partition layer 1300c forms a deeper step between the first partition 1310 and the second partition 1320, so it can trap a larger amount of organic material and thus, it is possible to prevent an overflow of the cover layer 800 into the bending area BA more effectively.

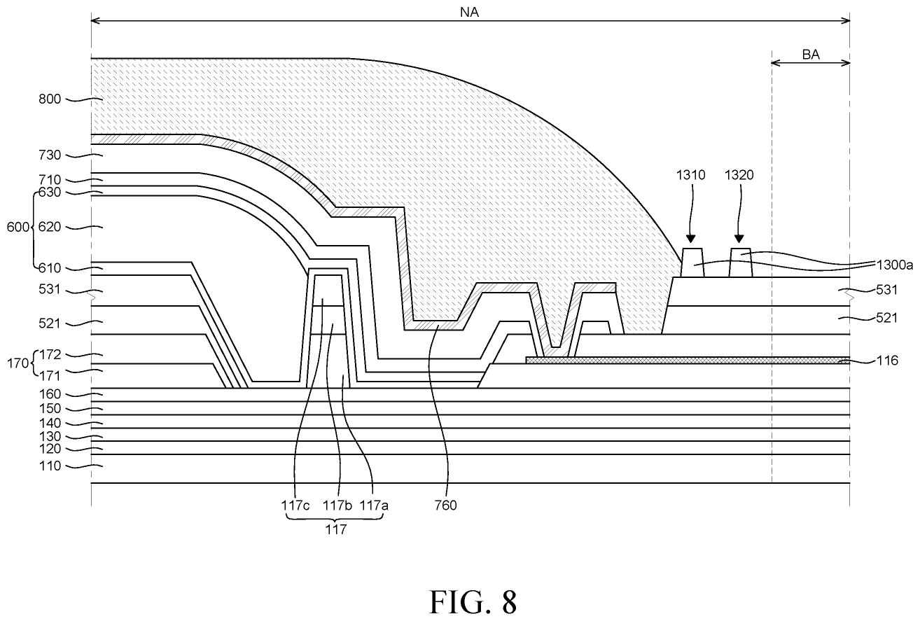

FIG. 8 is a cross-sectional view of a display device according to another exemplary embodiment of the present disclosure.

Referring to FIG. 8, the partition 1300 may be formed in a single layer. The first partition 1310 and the second partition 1320 may include the first partition layer 1300a.

The first partition layer 1300a may be formed of the same material as the insulating layer 730. The first partition layer 1300a may be formed simultaneously with the insulating layer 730, or may be formed in a separate process.

The second partition layer 1300b may be removed on the first partition layer 1300a.

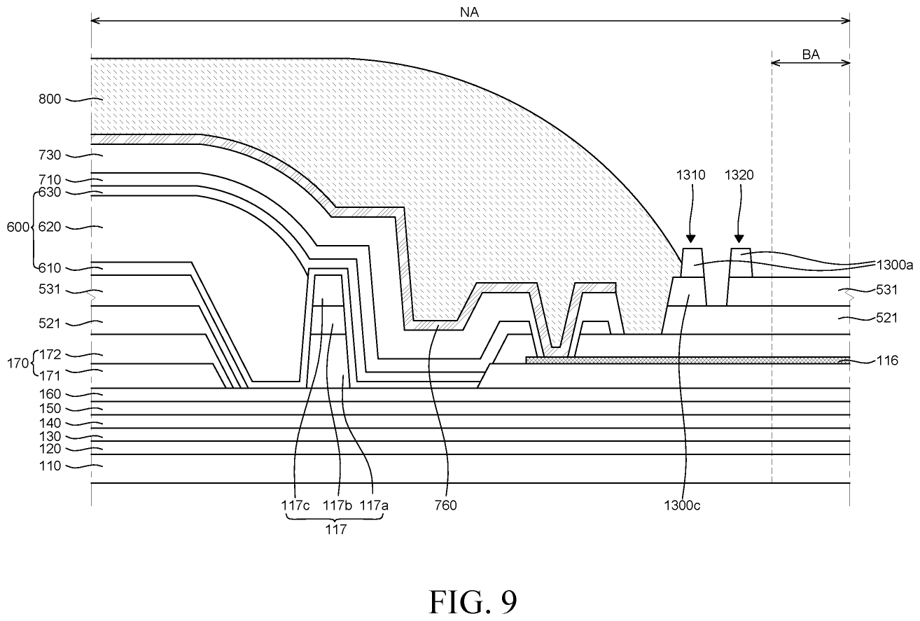

FIG. 9 is a cross-sectional view of a display device according to another exemplary embodiment of the present disclosure.

Referring to FIG. 9, the partition 1300 may further include the third partition layer 1300c disposed below the first partition layer 1300a. The third partition layer 1300c may be formed of the same material as that of the spacer 530, the bank 520, or the second protective layer 172. The third partition layer 1300c may be formed simultaneously with the spacer 530, the bank 520, or the second protective layer 172, or may be formed in a separate process. For another example, the third partition layer 1300c may be formed of the same material as that of the fourth protective layer 521, the fifth protective layer 531, or the second protective layer 172. The third partition layer 1300c may be formed simultaneously with the fourth protective layer 521, the fifth protective layer 531, or the second protective layer 172, or may be formed in a separate process.

The third partition layer 1300c can be formed by etching a portion of the fourth protective layer 521, the fifth protective layer 531, or the second protective layer 172. For example, when forming the spacer 530, the bank 520, and a hole in the second protective layer 172 in the active area AA, process conditions may be adjusted, so that the fourth protective layer 521, the fifth protective layer 531, or the second protective layer 172 disposed in the first non-active area NA1 may be etched.

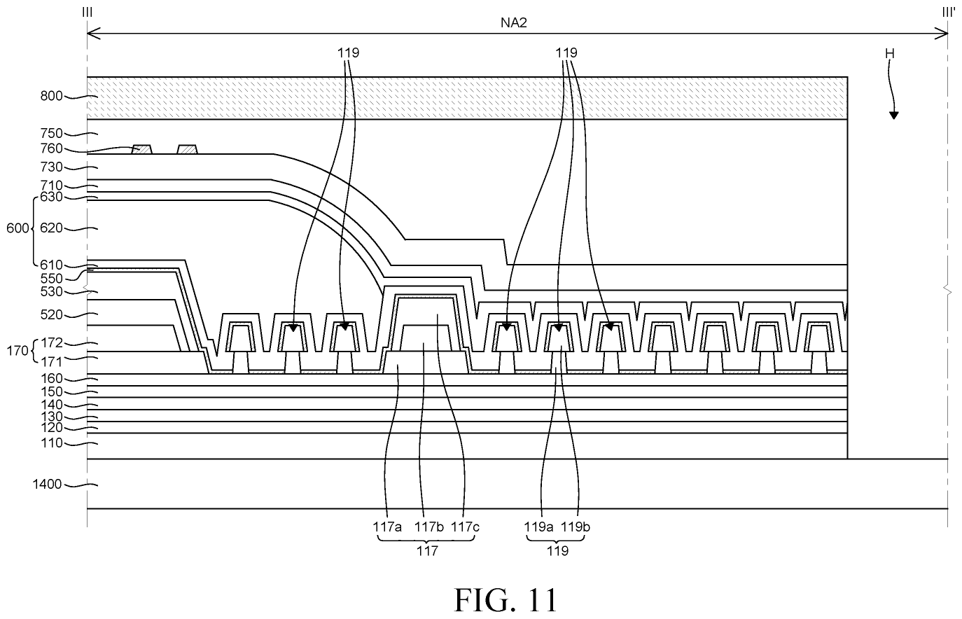

Hereinafter, a hole H disposed in the active area AA will be described in detail with reference to FIGS. 10 and 11.

FIG. 10 is a plan view of the second non-active area NA2 where a hole H is disposed according to an exemplary embodiment of the present disclosure. FIG. 11 is a cross-sectional view taken along line III-III′ of FIG. 10 according to an exemplary embodiment of the present disclosure.

Since the second non-active area NA2 of FIGS. 10 and 11 is substantially identical to that of the display device of FIG. 7 except for structures 119, duplicate descriptions will be omitted.

The substrate 110 may further include a hole H in the active area AA. The second non-active area NA2 may be further included between the hole H and the active area AA.

The hole H may be an empty space for placing an optical component such as a camera in the active area AA. By cutting a portion of the substrate 110 disposed on a backplate 1400 and the insulating layer, the protective layer, the encapsulation layer, and the cover layer disposed on the substrate 110, the hole H in which optical components are disposed may be formed. For another example, a portion of the display device may be cut so that it can be cut into a notch shape or an area for disposing optical components in various shapes may be formed.

The second non-active area NA2 may include the dam portion 117 and a plurality of the structures 119 to prevent penetration of moisture and oxygen through the hole H. The structure 119 may include a first structure layer 119a and a second structure layer 119b disposed on the first structure layer 119a. In one embodiment, the structure 119 disconnects the second electrode 550 that extends from the active area to the second non-active area NA2.

The first structure layer 119a and the second structure layer 119b may be formed of the same material as the first protective layer 171 and the second protective layer 172 disposed in the active area AA, and exemplary embodiments of the present disclosure are not limited thereto. The first structure layer 119a and the second structure layer 119b may be formed through the same process as the first protective layer 171 and the second protective layer 172, and exemplary embodiments of the present disclosure are not limited thereto.

The insulating layer 730 formed of an organic material may be disposed on the dam portion 117 and the plurality of structures 119. A sharp step or bends occur between the components disposed in the active area AA and the dam portion 117 and structures 119 disposed on the substrate on which the protective layer is etched. The sharp step and bends are not covered, which may cause a defect in which some of internal components of the display device are visible from the outside. This reduces aesthetics for users because they recognize those as defects such as stains. Additionally, an insulating layer formed of an inorganic material is less effective in blocking moisture and oxygen penetrating from the outside of the display device than an insulating layer formed of an organic material. Alternatively, it cannot cover foreign materials or particles that may occur during a manufacturing process. Therefore, in the present disclosure, since the insulating layer 730 is formed of an organic material, the defects of stains occurring in the second non-active area NA2 can be eliminated, and the user's aesthetics can be improved.

FIG. 12 is a cross-sectional view of an emission unit according to an exemplary embodiment of the present disclosure. The description of the emission unit shown in FIG. 12 can be equally applied to FIG. 5.

A stack structure can be configured by stacking a plurality of emission units 540 between the first electrode 510 and the second electrode 550. Although three emission units are shown in FIG. 12, two or more emission units or a plurality of emission units may be configured, and embodiments of the present disclosure are not limited thereto.

Referring to FIG. 12, the emission units 540 may include a first emission unit 541, a second emission unit 542, and a third emission unit 543, and between the plurality of emission units 540, charge generation layers (CGL) 60 may be further disposed. For example, a first charge generation layer 61 may be disposed between the first emission unit 541 and the second emission unit 542, and a second charge generation layer 63 may be disposed between the second emission unit 542 and the third emission unit 543.

The emission element layer composed of the plurality of emission units may have a longer luminous efficiency and lifespan compared to an emission element layer composed of one organic layer or one emission unit. For example, since a plurality of emission units are connected in series to meet conditions of an emission amount or light intensity required for a display device, stress, current concentration due to resistance, or deterioration of a single organic layer or single emission unit is dispersed. Efficiency and lifespan of each emission unit can be increased, thereby improving reliability of the display device.

The charge generation layers CGL 60 are disposed between the plurality of emission units to control charge balance. The charge generation layers may include an N-type charge generation layer N-CGL and a P-type charge generation layer P-CGL. The N-type charge generation layer N-CGL serves to inject electrons into the emission unit, and the N-type charge generation layer N-CGL may be formed of an organic layer doped with an alkali metal such as lithium (Li), sodium (Na), potassium (K), or cesium (Cs), or an alkaline earth metal such as magnesium (Mg), strontium (Sr), barium (BA), or radium (Ra), but is not limited thereto. The P-type charge generation layer P-CGL serves to inject holes into the emission unit. The P-type charge generation layer P-CGL may be formed of an organic layer containing a P-type dopant, but is not limited thereto.

The first emission unit 541 may be disposed on the first electrode 510. The first emission unit 541 may include a first hole transport layer (HTL) 51, a first emission layer (EML) 52, and a first electron transport layer (ETL) 53. The first emission unit 541 may further include a hole injection layer HIL and/or an electron blocking layer EBL, and the hole injection layer HIL and the electron blocking layer EBL may disposed between the first electrode 510 and the first hole transport layer (HTL) 51.

The hole injection layer HIL may be disposed on the first electrode 510. The hole injection layer HIL may function to smoothly inject holes from the first electrode 510 into the first hole transport layer (HTL) 51.

The first hole transport layer (HTL) 51 may be disposed on the first electrode 510 or the hole injection layer HIL. The first hole transport layer (HTL) 51 may supply holes from the first electrode 510 or the hole injection layer HIL to the first emission layer (EML) 52. The first hole transport layer (HTL) 51 can be formed by applying two or more layers or two or more materials.

The first emission layer (EML) 52 may be disposed on the first hole transport layer (HTL) 51. The first emission layer (EML) 52 may generate light by recombining holes supplied through the first hole transport layer (HTL) 51 and electrons supplied through the first electron transport layer (ETL) 53.

The first emission layer (EML) 52 can emit light of one color of blue, deep blue, or sky blue. An emission area of the first emission layer (EML) 52 may range from 440 nm to 480 nm.

The first emission layer (EML) 52 may further include a first auxiliary emission layer above or below the first emission layer (EML) 52. The first auxiliary emission layer may be a single layer emitting light of blue, yellow-green, or red light, or may be a plurality of layers composed of a combination thereof.

The first emission layer (EML) 52 may be composed of at least one host and a dopant. Alternatively, the first emission layer (EML) 52 may be composed of a mixed host in which two or more hosts are mixed and at least one dopant. The mixed host may include a host with hole transport properties and a host with electron transport properties. When the first emission layer (EML) 52 may be composed of the mixed host, charge balance of the emission layer can be adjusted, thereby improving efficiency of the emission layer. The dopant may be formed of a fluorescent dopant or a phosphorescent dopant.

The first electron transport layer (ETL) 51 may be disposed on the first emission layer (EML) 52. The first electron transport layer (ETL) 51 may supply electrons received from the first charge generation layer 61 to the emission layer (EML) 52. Therefore, in the first emission layer (EML) 52, since holes supplied through the first hole transport layer (HTL) 51 and electrons supplied through the first electron transport layer (ETL) 53 are recombined, light can be generated.

The first electron transport layer (ETL) 53 can be configured by applying two or more layers or two or more materials. The electron injection layer EIL may be further formed on the first electron transport layer (ETL) 53.

To improve efficiency of the first emission layer (EML) 52, the electron blocking layer EBL and the hole blocking layer HBL may be further included. The electron blocking layer EBL may be disposed between the first hole transport layer (HTL) 51 and the first emission layer (EML) 52, and the hole blocking layer HBL may be disposed between the first electron transport layer (ETL) 53 and the first emission layer (EML) 52.

The first charge generation layer 61 may be disposed on the first emission unit 541. The first charge generation layer 61 may be disposed between the first emission unit 541 and the second emission unit 542.

The first charge generation layer 61 may include an N-type charge generation layer N-CGL that supplies electrons to the first emission unit 541 and a P-type charge generation layer P-CGL that supplies holes to the second emission unit 542. The N-type charge generation layer N-CGL may be disposed adjacent to the first emission unit 541, and the P-type charge generation layer P-CGL may be disposed adjacent to the second emission unit 542. For example, the N-type charge generation layer N-CGL may be disposed on the first emission unit 541, and the P-type charge generation layer P-CGL may be disposed on the N-type charge generation layer N-CGL.

The second emission unit 542 may be disposed on the first charge generation layer 61. The second emission unit 542 may include a second hole transport layer (HTL) 54, a second emission layer (EML) 55, and a second electron transport layer (ETL) 56. The second emission unit 542 may further include a hole injection layer HIL and/or an electron blocking layer EBL, and the hole injection layer HIL and the electron blocking layer EBL may be disposed between the first charge generation layer 61 and the second hole transport layer (HTL) 54.

The second hole transport layer (HTL) 54 may be disposed on the first charge generation layer 61. The second hole transport layer (HTL) 54 may supply holes from the P-type charge generation layer P-CGL of the first charge generation layer 61 to the second emission layer (EML) 55. The second hole transport layer (HTL) 54 can be formed by applying two or more layers or two or more materials.

The second emission layer (EML) 55 may be disposed on the second hole transport layer (HTL) 54. The second emission layer (EML) 55 may generate light by recombining holes supplied through the second hole transport layer (HTL) 54 and electrons supplied through the second electron transport layer (ETL) 56.

The second emission layer (EML) 55 may emit light of one color of blue, deep blue, or sky blue. In this case, the light emitted from an emission area of the second emission layer (EML) 55 may range from 440 nm to 480 nm.

The second emission layer (EML) 55 may emit light of one color of blue, deep blue, or sky blue. In this case, the emission area of the second emission layer (EML) 55 may range from 440 nm to 480 nm.

According to another exemplary embodiment of the present disclosure, the second emission layer (EML) 55 may emit yellow-green or green light. The second emission layer (EML) 55 may be a plurality of emission layers that emit yellow-green and red light, a plurality of emission layers that emit yellow and red light, and a plurality of emission layers that emit green and red light. When the second emission layer (EML) 55 emits yellow-green light, the emission area of the second emission layer (EML) 55 may range from 510 nm to 590 nm. When the second emission layer (EML) 55 emits green light, the emission area of the second emission layer (EML) 55 may range from 510 nm to 580 nm. When the second emission layer (EML) 55 is composed of a plurality of emission layers that emit yellow-green and red light, the emission area of the second emission layer (EML) 55 may range from 510 nm to 650 nm. When the second emission layer (EML) 55 is composed of a plurality of emission layers that emit yellow and red light, the emission area of the second emission layer (EML) 55 may be range from 540 nm to 650 nm. When the second emission layer (EML) 55 is composed of a plurality of emission layers that emit green and red light, the emission area of the second emission layer (EML) 55 may range from 510 nm to 650 nm.

The second emission layer (EML) 55 may further include a second auxiliary emission layer above or below the second emission layer (EML) 55. The second auxiliary emission layer may be a single layer emitting blue, yellow-green, or red light, or may be a plurality of layers composed of a combination thereof.

The second emission layer (EML) 55 may be composed of at least one host and a dopant. Alternatively, the second emission layer (EML) 55 may be composed of a mixed host in which two or more hosts are mixed and at least one dopant. The mixed host may include a host with hole transport properties and a host with electron transport properties. When the second emission layer (EML) 55 may be composed of the mixed host, charge balance of the emission layer can be adjusted, thereby improving efficiency of the emission layer. The dopant may be formed of a fluorescent dopant or a phosphorescent dopant.

The second electron transport layer (ETL) 56 may be disposed on the second emission layer (EML) 55. The second electron transport layer (ETL) 56 may supply electrons received from the second charge generation layer 62 to the second emission layer (EML) 55. Therefore, in the second emission layer (EML) 55, since holes supplied through the second hole transport layer (HTL) 54 and electrons supplied through the second electron transport layer (ETL) 56 are recombined, light can be generated.

The second electron transport layer (ETL) 56 can be configured by applying two or more layers or two or more materials. The electron injection layer EIL may be further formed on the second electron transport layer (ETL) 56.

To improve efficiency of the second emission layer (EML) 55, an electron blocking layer EBL and a hole blocking layer HBL may be further included. The electron blocking layer EBL may be disposed between the second hole transport layer (HTL) 54 and the second emission layer (EML) 55, and the hole blocking layer HBL may be disposed between the second electron transport layer ETL 55 and the second emission layer (EML) 55.

The second charge generation layer 62 may be disposed on the second emission unit 542. The second charge generation layer 62 may be disposed between the second emission unit 542 and the third emission unit 543.

The second charge generation layer 62 may include an N-type charge generation layer N-CGL that supplies electrons to the second emission unit 542 and a P-type charge generation layer P-CGL that supplies holes to the third emission unit 543. The N-type charge generation layer N-CGL may be disposed adjacent to the second emission unit 542, and the P-type charge generation layer P-CGL may be disposed adjacent to the third emission unit 543. For example, the N-type charge generation layer N-CGL may be disposed on the second emission unit 542, and the P-type charge generation layer P-CGL may be disposed on the N-type charge generation layer N-CGL.

The third emission unit 543 may be disposed on the second charge generation layer 62. The third emission unit 543 may include a third hole transport layer (HTL) 57, a third emission layer (EML) 58, and a third electron transport layer (ETL) 59. The third emission unit 543 may further include a hole injection layer HIL and/or an electron blocking layer EBL, and the hole injection layer HIL and the electron blocking layer EBL may be disposed between the second charge generation layer 62 and the third hole transport layer (HTL) 57.

The third hole transport layer (HTL) 57 may be disposed on the second charge generation layer 62. The third hole transport layer (HTL) 57 may supply holes from the P-type charge generation layer P-CGL of the second charge generation layer 62 to the third emission layer (EML) 58. The third hole transport layer (HTL) 57 can be formed by applying two or more layers or two or more materials.

The second emission layer (EML) 58 may be disposed on the third hole transport layer (HTL) 57. The third emission layer (EML) 58 may generate light by recombining holes supplied through the third hole transport layer (HTL) 57 and electrons supplied through the third electron transport layer (ETL) 59.

The third electron transport layer (ETL) 59 may be disposed on the third emission layer (EML) 58. The third electron transport layer (ETL) 59 may supply electrons received from the second electrode 550 to the third emission layer (EML) 58. Therefore, in the third emission layer (EML) 58, since holes supplied through the third hole transport layer (HTL) 57 and electrons supplied through the third electron transport layer (ETL) 59 are recombined, light can be generated.

The third emission layer (EML) 58 may emit light of one color of blue, deep blue, or sky blue. An emission area of the third emission layer (EML) 58 may range from 440 nm to 480 nm.

The third emission layer (EML) 58 may further include a third auxiliary emission layer above or below the third emission layer (EML) 58. The third auxiliary emission layer may be a single layer emitting blue, yellow-green, or red light, or may be a plurality of layers composed of a combination thereof.

According to another exemplary embodiment of the present disclosure, the third emission layer (EML) 58 may emit yellow-green or green light. Since a description thereof is substantially identical to that of the second emission layer (EML) 55, the description will be omitted.

The third emission layer (EML) 58 may be composed of at least one host and a dopant. Alternatively, the third emission layer (EML) 58 may be composed of a mixed host in which two or more hosts are mixed and at least one dopant. The mixed host may include a host with hole transport properties and a host with electron transport properties. When the second emission layer (EML) 55 may be composed of the mixed host, charge balance of the emission layer can be adjusted, thereby improving efficiency of the emission layer. The dopant may be formed of a fluorescent dopant or a phosphorescent dopant.

The third electron transport layer (ETL) 59 can be formed by applying two or more layers or two or more materials. The electron injection layer EIL may be further formed on the third electron transport layer (ETL) 59.

To improve efficiency of the third emission layer (EML) 58, an electron blocking layer EBL and a hole blocking layer HBL may be further included. The electron blocking layer EBL may be disposed between the third hole transport layer (HTL) 57 and the third emission layer (EML) 58, and the hole blocking layer HBL may be disposed between the third electron transport layer (ETL) 59 and the third emission layer (EML) 58.

According to an exemplary embodiment of the present disclosure, at least two or more emission layers among the first emission layer (EML) 52 to the third emission layer (EML) 58 in the first emission unit 541, the second emission unit 542, and the third emission unit 543 may be emission layers that emit light of the same color. For example, at least two of the first emission layer (EML) 52 to the third emission layer (EML) 58 may be emission layers emitting blue light. For example, the first emission layer (EML) 52 and the second emission layer (EML) 55 may emit light of the same color. For another example, the first emission layer (EML) 52 and the third emission layer (EML) 58 may emit light of the same color. The other emission layer that does not emit light of the same color may be the second emission layer (EML) 55 or the third emission layer (EML) 58. For example, the other emission layer may be composed of a yellow-green or green emission layer. For another example, the other emission layers may be composed of red, yellow-green, and green emission layers. For another example, the other emission layers may be composed of red, yellow-green, and yellow-green emission layers. For another example, the other emission layer may be composed of red, green, and green emission layers.

The exemplary embodiments of the present disclosure can also be described as follows:

According to an aspect of the present disclosure, a display device may comprise a substrate including an active area and a first non-active area adjacent to the active area and including a bending area, a dam portion disposed on the substrate, an encapsulation layer disposed on the dam portion, a touch unit disposed on the encapsulation layer, a cover layer disposed on the touch unit, and a partition in contact with the cover layer.

The partition may be disposed between the dam portion and the bending area.

The display device may further comprise a thin film transistor disposed in the active area, a planarization layer disposed on the thin film transistor, a bank disposed on the planarization layer, and a spacer disposed on the bank, wherein the touch unit may include a buffer layer disposed on the encapsulation layer, a connection electrode disposed on the buffer layer, an insulating layer disposed on the connection electrode, and a first touch electrode and a second touch electrode disposed on the insulating layer.

The touch unit may further include a planarization layer disposed on the first touch electrode and the second touch electrode.

The partition may include a first partition layer formed of the same material as a material that constitutes the insulating layer.

The partition may further include a third partition layer disposed below the first partition layer, and wherein the third partition layer may be formed of the same material as that of the spacer.

The partition may include, a first partition layer formed of the same material as a material constituting the insulating layer, and a second partition layer disposed on the first partition layer and formed of the same material as the planarization layer.

The partition may further include a third partition layer disposed below the first partition layer, and wherein the third partition layer may be formed of the same material as at least one of materials constituting the spacer, the bank, and the protective layer.

The display device may further comprise a fifth protective layer disposed below the partition and formed of the same material as a material constituting the spacer, and a fourth protective layer disposed below the fifth protective layer and formed of the same material as a material constituting the bank.

The partition and the insulating layer may be formed of an organic material.

The encapsulation layer may include a first encapsulation layer formed of an inorganic material, a second encapsulation layer disposed on the first encapsulation layer and formed of an organic material, and a third encapsulation layer disposed on the second encapsulation layer and formed of an inorganic material, wherein the cover layer may be formed of the same material as a material constituting the second encapsulation layer.

The display device may further comprise a touch line connected to the touch unit, and a connection line disposed in the bending area, wherein the touch line and the connection line may be in contact between the dam portion and the partition.

The dam portion may be formed of the same material as at least one of the planarization layers, the bank, and the spacer.

The cover layer may cover the touch unit and the touch line.

The substrate may further include a hole surrounded by the active area and a second non-active area disposed between the hole and the active area, and include a structure disposed in the second non-active area.

The insulating layer and the cover layer may cover the structure.

The insulating layer may be formed of an organic material.

What is claimed is:

1. A display device, comprising:
a substrate including an active area and a first non-active area adjacent to the active area, the first non-active area including a bending area;
a dam portion on the substrate;
an encapsulation layer on the dam portion;
a touch unit configured to sense touch of the display device, the touch unit on the encapsulation layer;
a cover layer on the touch unit; and
a partition in contact with the cover layer.

2. The display device of claim 1, wherein the partition is between the dam portion and the bending area in the first non-active area.

3. The display device of claim 1, further comprising:
a thin film transistor in the active area;
a planarization layer on the thin film transistor;
a bank on the planarization layer; and
a spacer on the bank,
wherein the touch unit includes:
a buffer layer on the encapsulation layer;
a connection electrode on the buffer layer;
an insulating layer on the connection electrode; and
a first touch electrode and a second touch electrode on the insulating layer.

4. The display device of claim 3, wherein the touch unit further includes a planarization layer on the first touch electrode and the second touch electrode.

5. The display device of claim 3, wherein the partition comprises a first partition layer comprising a same material as the insulating layer.

6. The display device of claim 5, wherein the partition further comprises a third partition layer below the first partition layer, the third partition layer comprising a same material as the spacer.

7. The display device of claim 4, wherein the partition comprises:
a first partition layer comprising a same material as the insulating layer; and
a second partition layer on the first partition layer, the second partition layer comprising a same material as the planarization layer.

8. The display device of claim 7, wherein the partition further comprises:
a third partition layer below the first partition layer, the third partition layer comprising a same material as one of the spacer or the bank.

9. The display device of claim 5, further comprising:
a fifth protective layer below the partition, the fifth protective layer comprising a same material as the spacer; and
a fourth protective layer below the fifth protective layer, the fourth protective layer comprising a same material as the bank.

10. The display device of claim 4, wherein the partition and the insulating layer comprise an organic material.

11. The display device of claim 1, wherein the encapsulation layer comprises:
a first encapsulation layer comprising an inorganic material;
a second encapsulation layer on the first encapsulation layer, the second encapsulation layer comprising an organic material; and
a third encapsulation layer on the second encapsulation layer, the third encapsulation layer comprising an inorganic material,
wherein the cover layer comprises a same material as the second encapsulation layer.

12. The display device of claim 3, further comprising:
a touch line connected to the touch unit; and
a connection line in the bending area,
wherein the touch line and a portion of the connection line are in contact between the dam portion and the partition.

13. The display device of claim 12, wherein the dam portion comprises a same material as at least one of the planarization layer, the bank, or the spacer.

14. The display device of claim 12, wherein the cover layer covers the touch unit and the touch line.

15. The display device of claim 3, wherein the substrate further comprises a hole surrounded by the active area and a second non-active area between the hole and the active area, the second non-active area comprising a structure in the second non-active area that disconnects an electrode that extends from the active area to the second non-active area.

16. The display device of claim 15, wherein the insulating layer and the cover layer cover the structure.

17. The display device of claim 16, wherein the insulating layer comprises an organic material.

18. A display device, comprising:
a substrate including an active area and a non-active area around the active area, the non-active area including a bending area;
a dam portion in the non-active area, the dam portion around the active area;
an encapsulation layer on the dam portion; and
a touch unit on the encapsulation layer, the touch unit comprising:
a first touch electrode;
a second touch electrode; and
an insulating layer between the first touch electrode and the second touch electrode, the insulating layer comprising an organic material.

19. The display device of claim 18, wherein the insulating layer comprises silicon oxycarbon epoxy, polyimide, polyethylene, or acrylate.

20. The display device of claim 18, further comprising:
a cover layer on the touch unit; and
a partition between the dam portion and the bending area,
wherein the partition prevents the cover layer from being disposed in the bending area.

21. The display device of claim 20, wherein the insulating layer comprises silicon oxycarbon epoxy, polyimide, polyethylene, or acrylate.

22. The display device of claim 20, wherein the cover layer covers the touch unit and a touch line that is connected to the touch unit.

23. A display device comprising:
a substrate including an active area and a non-active area, the non-active area including a bending area;
a light emitting element in the active area, the light emitting element configured to emit light;
a dam in the non-active area of the substrate;
an encapsulation layer on the light emitting element in the active area, the encapsulation layer extending from the active area to the non-active area and in contact with the dam in the non-active area;
a partition between the dam and the bending area in the non-active area; and
a cover layer on the encapsulation layer, the cover layer extending from the active area to the non-active area such that an end of the cover layer contacts the partition in the non-active area.

24. The display device of claim 23, further comprising:
a touch unit configured to sense touch and located between the encapsulation layer and the cover layer in the active area, the touch unit comprising:
a buffer layer on the encapsulation layer;
a connection electrode on the buffer layer;
an insulating layer on the connection electrode; and
a first touch electrode and a second touch electrode on the insulating layer.

25. The display device of claim 24, wherein the partition and the insulating layer each comprise an organic material.

26. The display device of claim 25, wherein the partition comprises:
a first partition layer comprising a same material as the insulating layer; and
a second partition layer on the first partition layer.

27. The display device of claim 26, further comprising:
a planarization layer between the cover layer and the first touch electrode and the second touch electrode, the second partition layer comprising a same material as the planarization layer.

28. The display device of claim 24, further comprising:
a touch line that is connected to the touch unit; and
a connection line in the non-active area,
wherein a connection between the connection line and the touch line is located between the dam and the partition in the non-active area.

29. The display device of claim 28, wherein the cover layer extends past an end of the touch line in the non-active area.

30. The display device of claim 28, wherein the partition is non-overlapping with the connection.
